(19) United States
(12) Patent Application Publication
(10) Pub. No.: US 2025/0253206 A1
(43) Pub. Date: Aug. 7, 2025

(54) INTEGRATED COOLING ASSEMBLIES FOR ADVANCED DEVICE PACKAGING AND METHODS OF MANUFACTURING THE SAME

(71) Applicant: Adeia Semiconductor Technologies LLC, San Jose, CA (US)

(72) Inventors: Belgacem Haba, Saratoga, CA (US); Ron Zhang, Sunnyvale, CA (US); Bongsub Lee, Santa Clara, CA (US); Kyong-Mo Bang, Fremont, CA (US); Suhail Jaan Sadiq, Dublin, CA (US); Thomas Workman, San Jose, CA (US); Rajesh Katkar, Milpitas, CA (US); Cyprian Emeka Uzoh, San Jose, CA (US)

(21) Appl. No.: 18/908,493

(22) Filed: Oct. 7, 2024

Related U.S. Application Data
(60) Provisional application No. 63/550,778, filed on Feb. 7, 2024.
(60) Provisional application No. 63/575,134, filed on Apr. 5, 2024.
(60) Provisional application No. 63/670,330, filed on Jul. 12, 2024.

(51) Int. Cl. H01L 23/46; H01L 21/50; H01L 23/00; H01L 23/31

(52) U.S. Cl. CPC H01L 23/46; H01L 21/50; H01L 23/3185; H01L 24/32; H01L 2224/32245

(57) ABSTRACT

A device package includes an integrated cooling assembly. The integrated cooling assembly includes a semiconductor portion and a metal cold plate attached to the semiconductor portion. The semiconductor portion includes a semiconductor device. The metal cold plate includes a base surface spaced apart from the semiconductor device to collectively define a coolant channel therebetween. The metal cold plate further includes a side wall extending downwardly from the base surface to define a perimeter of the coolant channel. The metal cold plate further includes cavity dividers extending downwardly from the base surface towards the semiconductor device.

### CROSS-REFERENCE TO RELATED APPLICATIONS

The present disclosure claims the benefit of U.S. Provisional Patent Application No. 63/550,778, filed Feb. 7, 2024, U.S. Provisional Patent Application No. 63/575,134, filed Apr. 5, 2024, and U.S. Provisional Patent Application No. 63/670,330, filed Jul. 12, 2024, each of which is hereby incorporated by reference herein in its entirety.

### FIELD

The present disclosure relates to advanced packaging for microelectronic devices, and in particular, cooling systems for device packages and methods of manufacturing the same.

### BACKGROUND

Energy consumption poses a critical challenge for the future of large-scale computing as the world's computing energy requirements are rising at a rate that most would consider unsustainable. Some models predict that the information, communication and technology (ICT) ecosystem could exceed 20% of global electricity use by 2030, with direct electrical consumption by large-scale computing centers accounting for more than one-third of that energy usage. A significant portion of the energy used by such large-scale computing centers is devoted to cooling, since even small increases in operating temperatures can negatively impact the performance of microprocessors, memory devices, and other electronic components. While some of this energy is expended to operate the cooling systems that are directly cooling the chips (e.g., heat spreaders, heat pipes, etc.), energy consumption/costs for indirect cooling can also be quite staggering. Indirect cooling energy costs include, for example, cooling or air conditioning of data center buildings. Data center buildings can house thousands, to tens of thousands or more, of high performance chips in server racks, and each of those high performance chips is a heat source. An uncontrolled ambient temperature in a data center will adversely affect the performance of the individual chips, and the data center system performance as a whole.

Thermal dissipation in high-power density chips (semiconductor devices/die) is also a critical challenge as improvements in chip performance, e.g., through increased gate or transistor density due to advanced processing nodes, evolution of multi-core microprocessors, etc., have resulted in increased power density and a corresponding increase in thermal flux that contributes to elevated chip temperatures. Higher density of transistors also increases the length of metal wiring on the chips, which generates its own additional thermal flux due to Joule heating of these wires due to higher currents. These elevated temperatures are undesirable as they can degrade the chip's operating performance, efficiency, reliability, and amount of remaining life. Cooling systems used to maintain the chip at a desired operating temperature typically remove heat using one or more heat dissipation devices, e.g., thermal spreaders, heat pipes, cold plates, liquid cooled heat pipe systems, thermal-electric coolers, heat sinks, etc. One or more thermal interface material(s), such as, for example, thermal paste, thermal adhesive, or thermal gap filler, may be used to facilitate heat transfer between the surfaces of a chip and heat dissipation device(s). A thermal interface material(s) (TIM(s)) is any material that is inserted between two components to enhance the thermal coupling therebetween. Unfortunately, the combined thermal resistance of (i) the thermal resistance of interfacial boundary regions between a TIM(s) and the chip and/or the heat dissipation device(s), and (ii) the thermal resistance of a thermal interface material(s) itself can inhibit heat transfer from the chip to the heat dissipation devices, undesirably reducing the cooling efficiency of the cooling system.

Generally speaking, there are multiple components between the heat dissipating sources (i.e., active circuitry) in the chips and the heat dissipation devices, each of which contributes to the system thermal resistance cumulatively along the heat transfer paths and raises chip junction temperatures from the ambient.

Such cooling systems can suffer from high costs due to the design and manufacture of system components.

Accordingly, there exists a need in the art for improved design for cost effective cooling systems, by reducing system thermal resistance, and methods of manufacturing the same.

### SUMMARY

Embodiments herein provide integrated cooling assemblies embedded in advanced device packages. Advantageously, the integrated cooling assemblies minimize or reduce system thermal resistance, simplify fabrication of and/or reduce the cost of forming cooling channels inside the device package by forming cooling channels in materials made of metal and/or molding material.

A first general aspect includes, a device package including an integrated cooling assembly. The integrated cooling assembly includes a semiconductor portion and a metal cold plate attached to the semiconductor portion. The semiconductor portion includes a semiconductor device. The metal cold plate includes a base surface spaced apart from the semiconductor device to collectively define a coolant channel therebetween. The metal cold plate further includes a side wall extending downwardly from the base surface to define a perimeter of the coolant channel. The metal cold plate further includes a plurality of cavity dividers extending downwardly from the base surface towards the semiconductor device.

Implementations of the device package may include one or more of the following features. The cavity dividers may be attached to the semiconductor device using adhesive.

Implementations of the device package may include one or more of the following features. The semiconductor device may be disposed on a substrate. The side wall of the metal cold plate may extend downwardly from the base surface to the substrate. The side wall may be attached to the substrate using adhesive.

Implementations of the device package may include one or more of the following features. The semiconductor portion may include molding material and the semiconductor device may be disposed in the molding material. The side wall of the metal cold plate may extend downwardly from sides of the base surface to the molding material. The side wall may be attached to the molding material using adhesive.

A second general aspect includes, a device package including an integrated cooling assembly. The integrated cooling assembly includes a semiconductor device disposed in a molding material. The integrated cooling assembly further includes a manifold disposed on the semiconductor device. The integrated cooling assembly further includes a metal cover attached to the manifold. The manifold includes a side wall extending between the molding material and the metal cover. The manifold further includes a plurality of cavity dividers extending between a backside of the semiconductor device and the metal cover. The side wall, a base surface of the metal cover, and a backside of the semiconductor device collectively define a coolant channel therebetween.

Implementations of the device package may include one or more of the following features. The metal cover may be attached to the manifold using adhesive along edges of the metal cover. The cavity dividers may be attached to a surface of the metal cover using adhesive.

A third general aspect includes a method of manufacturing the device package of the first general aspect. The method includes attaching the metal cold plate to a substrate comprising the semiconductor device to form the integrated cooling assembly. The integrated cooling assembly includes a cooling channel.

A fourth general aspect includes a method of manufacturing the device package of the second general aspect. The method including attaching the manifold to a substrate including the semiconductor device to form the integrated cooling assembly, wherein the integrated cooling assembly includes a cooling channel.

### BRIEF DESCRIPTION OF THE DRAWINGS

The above and other objects and advantages of the disclosure will be apparent upon consideration of the following detailed description, taken in conjunction with the accompanying drawings, in which:

FIG. 1 illustrates a device package with an external heat sink;

FIG. 2A is a schematic plan view of an example of a system panel, in accordance with embodiments of the present disclosure;

FIG. 2B is a schematic partial sectional side view of a device package mounted on a PCB, in accordance with embodiments of the present disclosure;

FIG. 2C is a schematic exploded isometric view of the device package in FIG. 2B, in accordance with some embodiments of the disclosure;

FIG. 2D is a schematic isometric, top, and bottom view of the cold plate in FIG. 2C, in accordance with some embodiments of the disclosure;

FIGS. 2E and 2F are schematic sectional views of the device package of FIG. 2C, in accordance with some embodiments of the disclosure;

FIG. 2G is a schematic exploded isometric view of the device package in FIG. 2B;

FIG. 2H is a schematic sectional view of an example device package, in accordance with embodiments of the present disclosure, that may be used with the system panel;

FIG. 2I is a schematic sectional view of an integrated cooling assembly of the device package, in accordance with embodiments of the present disclosure;

FIG. 3A is a schematic top view and sectional views of an integrated cooling assembly, in accordance with some embodiments of the disclosure;

FIGS. 3B and 3C are schematic sectional views of examples of the integrated cooling assembly of FIG. 3A, in accordance with some embodiments of the disclosure;

FIG. 4 is schematic sectional views of an example of an integrated cooling assembly, in accordance with some embodiments of the disclosure;

FIG. 5A is a schematic exploded isometric view of a device package, in accordance with some embodiments of the disclosure;

FIGS. 5B-5D are schematic sectional views of examples of the device package of FIG. 5A, in accordance with some embodiments of the disclosure;

FIG. 6A is a schematic exploded isometric view of a device package, in accordance with some embodiments of the disclosure;

FIGS. 6B and 6C are schematic sectional views of examples of the device package of FIG. 6A, in accordance with some embodiments of the disclosure;

FIGS. 7A-7B show example methods that can be used to manufacture the integrated cooling assemblies described herein;

FIG. 8A is a schematic sectional view of a device package, in accordance with some embodiments of the disclosure; and

FIG. 8B is a schematic sectional view of another example device package, in accordance with embodiments of the present disclosure, that may be used with the system panel.

The figures herein depict various embodiments of the disclosure for purposes of illustration only. It will be appreciated that additional or alternative structures, assemblies, systems, and methods may be implemented within the principles set out by the present disclosure.

### DETAILED DESCRIPTION

Embodiments herein provide for integrated cooling assemblies embedded within a device package. The integrated cooling assemblies have an elegant design which minimizes or reduces the system thermal resistance, reduces the complexity of integrated cooling assembly manufacturing and reduces the overall manufacturing costs of such. Manufacturing efficiency is improved by forming cavity dividers in a metal cold plate (or in a molding material having a metal cover attached thereto) to define plural cavity coolant channels through which coolant fluid flows in order to remove heat from a surface of a semiconductor device.

As used herein, the term “substrate” means and includes any workpiece, wafer, or article that provides a base material or supporting surface from which or upon which components, elements, devices, assemblies, modules, systems, or features of the heat-generating devices, packaging components, and cooling assembly components described herein may be formed or mounted. The term “substrate” also includes semiconductor substrates that provide a supporting material upon which elements of a semiconductor device are fabricated or attached, and any material layers, features, and/or electronic devices formed thereon, therein, or therethrough. Examples of substrate material that may be used in applications that generate high thermal density include, but are not limited to, Si, GaN, SiC, InP, GaP, InGaN, AlGaInP, AlGaAs, etc.

As described below, the semiconductor substrates herein generally have a “device side,” e.g., the side on which semiconductor device elements are fabricated, such as transistors, resistors, and capacitors, and a “backside” that is opposite the device side. The term “active side” should be understood to include a surface of the device side of the substrate and may include the device side surface of the semiconductor substrate and/or a surface of any material layer, device element, or feature formed thereon or extending outwardly therefrom, and/or any openings formed therein. Thus, it should be understood that the material(s) that forms the active side may change depending on the stage of device fabrication and assembly. Similarly, the term “non-active side” (opposite the active side) includes the non-active side of the substrate at any stage of device fabrication, including the surfaces of any material layer, any feature formed thereon, or extending outwardly therefrom, and/or any openings formed therein. Thus, the terms “active side” or “non-active side” may include the respective surfaces of the semiconductor substrate at the beginning of device fabrication and any surfaces formed during material removal, e.g., after substrate thinning operations. Depending on the stage of device fabrication or assembly, the terms “active sides” and “non-active sides” are also used to describe surfaces of material layers or features formed on, in, or through the semiconductor substrate, whether or not the material layers or features are ultimately present in the fabricated or assembled device. For example, in some instances, the term “active side” is used to indicate a surface of a substrate that will in the future, but does not yet, include semiconductor device elements.

Spatially relative terms are used herein to describe the relationships between elements, such as the relationships between substrates, heat-generating devices, cooling assembly components, device packaging components, and other features described below. Unless the relationship is otherwise defined, terms such as “above,” “over,” “upper,” “upwardly,” “outwardly,” “on,” “below,” “under,” “beneath,” “lower,” “top,” “bottom” and the like are generally made with reference to the X, Y, and Z directions set forth by X, Y and Z axes in the drawings. Thus, it should be understood that the spatially relative terms used herein are intended to encompass different orientations of the substrate and, unless otherwise noted, are not limited by the direction of gravity. Unless the relationship is otherwise defined, terms describing the relationships between elements such as “disposed on,” “embedded in,” “coupled to,” “connected by,” “attached to,” “bonded to,” and the like, either alone or in combination with a spatially relevant term, include both relationships with intervening elements and direct relationships where there are no intervening elements. Furthermore, the term “horizontal” is generally made with reference to the X-axis direction and the Y-axis direction set forth in the drawings. The term “vertical” is generally made with reference to the Z-axis direction set forth in the drawings.

Various embodiments disclosed herein include bonded structures in which two or more elements are directly bonded to one another without an intervening adhesive (referred to herein as “direct bonding,” “direct dielectric bonding,” or “directly bonded”). The resultant bonds formed by this technique may be described as “direct bonds” and/or “direct dielectric bonds”. In some embodiments, direct bonding includes the bonding of a single material on the first of the two or more elements and a single material on a second one of the two or more elements, where the single material on the different elements may or may not be the same. For example, bonding a layer of one inorganic dielectric (e.g., silicon oxide) to another layer of the same or different inorganic dielectric. As discussed in more detail below, the process of direct bonding (e.g., direct dielectric bonding) provides a reduction of thermal resistance between a semiconductor device and a cold plate. Examples of dielectric materials used in direct bonding include oxides, nitrides, oxynitrides, carbonitrides, and oxycarbonitrides, etc., such as, for example, silicon oxide, silicon nitride, silicon oxynitride, silicon carbonitride, silicon oxycarbonitride, etc. Direct bonding can also include bonding of multiple materials on one element to multiple materials on the other element (e.g., hybrid bonding). As used herein, the term “hybrid bonding” refers to a species of direct bonding having both i) at least one (first) nonconductive feature directly bonded to another (second) nonconductive feature, and ii) at least one (first) conductive feature directly bonded to another (second) conductive feature, without any intervening adhesive. The resultant bonds formed by this technique may be described as “hybrid bonds” and/or “direct hybrid bonds”. In some hybrid bonding embodiments, there are many first conductive features, each directly bonded to a second conductive feature, without any intervening adhesive. In some embodiments, nonconductive features on the first element are directly bond to nonconductive features of the second element at room temperature without any intervening adhesive, which is followed by bonding of conductive features of the first element directly bonded to conductive features of the second element via annealing at slightly higher temperatures (e.g., >100° C., >200° C., >250° C., >300° C., etc.).

Unless otherwise noted, the terms “cooling assembly” and “integrated cooling assembly” generally refers to a semiconductor device and a cold plate, or a semiconductor device, a molding material, and a metal cover. The cold plate may be made from or include a metal material, such as aluminum or copper. In some embodiments, the cold plate may be made from a molding material. The metal cover may be made from or include a metal material, such as aluminum or copper, similar to the material from which the cold plate is made. For simplicity, the metal cover or metal cover will be referred to just as a cover from hereon. Typically, the cold plate is formed with recessed surfaces that define one or more fluid cavities (e.g., coolant channel(s), coolant channel volume(s), or coolant chamber volume(s)) between the cold plate and the semiconductor device. In embodiments where the cold plate is formed with plural fluid cavities, each fluid cavity may be defined by cavity dividers and/or sidewalls of the cold plate. For example, cavity dividers may be spaced apart from each other and extend laterally between opposing cold plate sidewalls (e.g., in one direction between a first pair of opposing cold plate sidewalls, or in two directions between orthogonal pairs of opposing cold plate sidewalls). The cavity dividers and the cold plate sidewalls may collectively define adjacent fluid cavities therebetween. The cold plate is made from or includes a metal material, such as aluminum or copper, similar to the material from which the cover is made. For simplicity, the metal cold plate will be referred to just as a cold plate from hereon. The cold plate may comprise a polymer material. The cold plate may be attached to the semiconductor device by use of a compliant adhesive layer.

In some embodiments, the integrated cooling assembly comprises a molding material, such as an epoxy or a polymer material. Any suitable molding material may be used, and may be referred to as a mold matrix. For example, a thermally conductive molding material with addition of thermally conductive particles to the mold matrix may be used. The thermally conductive particles may be metallic or non-metallic. A more thermally conductive molding material and/or a higher loading of the thermally conductive particles in the molding material may improve the thermal properties of the mold matrix and efficiency of the cooling system. The cold plate may be attached to the semiconductor portion or a substrate on which the semiconductor device is disposed on, by use of a sealing material layer or adhesive 242 or adhesive 333, or adhesive 433, or adhesive 436. In some embodiments, the adhesive is a compliant adhesive layer.

In some embodiments, a manifold may be formed on the semiconductor portion (e.g., the semiconductor device disposed in a molding material). The manifold may be made from or include a molding material and the molding material may comprise thermally conductive particles. The cover may be attached to the manifold. The cover may be further attached to a substrate, and the semiconductor device may be disposed on the same substrate. The manifold may be formed with recessed surfaces that define a fluid cavity (e.g., a coolant channel or coolant chamber volume) between the cover and the semiconductor device.

Beneficially, the backside of the semiconductor device is directly exposed to coolant fluids flowing through the integrated cooling assembly, thus providing for direct heat transfer therebetween. Unless otherwise noted, the integrated cooling assemblies described herein may be used with any desired fluid, e.g., liquid, gas, and/or vapor-phase coolants, such as water, glycol, etc. In some embodiments, the coolant fluid(s) may contain additives to enhance the conductivity of the coolant fluid(s) within the integrated cooling assemblies. The additives may comprise, for example, nano-particles of carbon nanotubes, nano-particles of graphene, and/or nano-particles of metal oxides. The concentration of these nano-particles may be less than 1%, less than 0.2%, or less than 0.05%. The coolant fluids may also contain a small amount of glycol or glycols (e.g., propylene glycol, ethylene glycol, etc.) to reduce frictional shear stress and drag coefficient in the coolant fluid(s) within the integrated cooling assembly.

Exemplary fluids available for use in the various thermal solution embodiments include: water (either purified or deionized), a glycol (e.g., ethylene glycol, propylene glycol), glycols mixed with water (e.g., ethylene glycol mixed with water (EGW) or propylene glycol mixed with water (PGW)), dielectric fluids (e.g. fluorocarbons, polyalphaolefin (PAO), isoparaffins, synthetic esters, or very high viscosity index (VHVI) oils), or mineral oils. Additionally, depending upon design and operating conditions, these fluids may be used in single-phase liquid, single-phase vapor, two-phase liquid/vapor or two-phase solid/liquid. All of these fluids and fluid mixtures will alter the thermohydraulic and heat transfer properties by altering the temperatures where phase change occurs, as well as meeting design temperature and pressure conditions for the component being cooled or warmed and the thermal solution being deployed. Additionally, multiple combinations of the fluid phases may be employed in various hybrid configurations to meet the particular cooling or warming needs of a respective implementation and still be within the scope of the contemplated embodiments.

Additionally, in some embodiments part or all the cooling is provided by gases. Exemplary gases include atmospheric air and/or one or more inert gases such as nitrogen. Atmospheric air may be taken to mean the mixture of different gases in Earth's atmosphere made up of about 78% nitrogen and 21% oxygen.

Depending on the design needs of a thermal solution system using the disclosed embodiments, engineered dielectric cooling fluids may be used. Some examples of dielectric fluids used for cooling semiconductors include: 3M™ Fluorinert™ Liquid FC-40—A non-flammable, dielectric fluid that can be used in direct contact with live electronics; 3M™ Novec™ Engineered Fluids-A non-flammable, dielectric fluid that can be used in direct contact with live electronics; Galden® PFPE (perfluoropolyether) products used as heat transfer fluids; EnSolv Fluoro HTF-A solvent with a high boiling point and low pour point that can be used for semiconductor wafer cooling. It is understood that in the selection of the cooling fluid, system design aspects such as operating temperatures and pressures, fluid flow rates, fluid viscosity, and other properties will require evaluation when selecting the appropriate cooling fluid.

In some embodiments, the cooling fluids may contain microparticles and/or nanoparticle additives to enhance the conductivity of the cooling fluid within the integrated cooling assemblies. Choi and Eastman (1995) from Argonne National Laboratory, U.S.A. (Yu et al., 2007) coined the word “nanofluid”. Nanofluids are engineered fluids prepared by suspending the nano-sized (1-100 nm) particles of metals/non-metals and their oxide(s) with a base/conventional fluid. The suspension of high thermal conductivity metals/non-metals and their oxides nanoparticles enhances the thermal conductivity and heat transfer ability, etc. of the base fluid. The additives to the underlying cooling fluid may comprise for example, nanoparticles of carbon nanotube, nanoparticles of graphene, or nanoparticles of metal oxides. When the cooling fluid contains microparticles, the microparticles are typically 10 microns or less in diameter. Silicon oxide microparticles may be used.

The volume concentration of these micro or nanoparticles may be less than 1%, less than 0.2%, or less than 0.05%. Depending upon the liquid and micro/nanoparticle type chosen for the cooling fluid, higher volume concentrations of 10% or less, 5% or less, or 2% or less may be used. The cooling fluids may also contain small amounts of glycol or glycols (e.g. propylene glycol, ethylene glycol etc.) to reduce frictional shear stress and drag coefficient in the cooling fluid within the integrated cooling assembly. The availability of different base fluids (e.g., water, ethylene glycol, mineral or other stable oils, etc.) and different nanomaterials provide a variety of nanomaterial options for nanofluid solutions to be used in the various embodiments. These nanomaterial option groups such as aforementioned metals (e.g., Cu, Ag, Fe, Au, etc.), metal oxides (e.g., TiO₂, Al₂O₃, CuO, etc.), carbons (e.g. CNTS, graphene, diamond, graphite . . . , etc.), or a mixture of different types of nanomaterials. Metal nanoparticles (Cu, Ag, Au . . . ), metal oxide nanoparticles (Al₂O₃, TiO₂, CuO), and carbon-based nanoparticles are commonly employed elements. Silicon oxide nanoparticles may also be used. Using cooling fluids with micro and/or nanoparticles when practicing the various embodiments disclosed herein can result in increased heat removal efficiencies and effectiveness.

The fluid control design aspects of specific embodiments may require the nanofluids to be magnetic to facilitate either movement or cessation of movement of the fluids within the semiconductor structures. Magnetic nanofluids (MNFs) are suspensions of a non-magnetic base fluid and magnetic nanoparticles. Magnetic nanoparticles may be coated with surfactant layers such as oleic acid to reduce particle agglomeration and/or settling. Magnetic nanoparticles used in MNFs are usually made of metal materials (ferromagnetic materials) such as iron, nickel, cobalt, as well as their oxides such as spinel-type ferrites, magnetite (Fe₃O₄), and so forth. The magnetic nanoparticles used in MNFs typically range in size from about 1 to 100 nanometers (nm).

This disclosure describes embodiments involving the architecture of system and component elements that can be employed to provide for the cooling of semi-conductor components, packaging, and boards. However, those skilled in the art will appreciate the disclosed components and arrangements can be deployed and used in scenarios where component heat up or thermal warm up is desired for a component that is currently outside the low end of the desired operational range. Components that are outside the low end of their operational range can, if started in a cold environment, experience thermal warping or cracking up to and including thermal overexpansion and contact separation that may impair the successful operation of the system. Therefore, in these scenarios, the architectures and embodiments disclosed herein can be used where the indirect thermal solutions supporting them are repurposed or operated in a hybrid configuration to provide warming fluids or heat transfer media to accomplish the warm-up or heat-up scenario. These scenarios are controlled by systems not shown here to bring temperatures up at a speed or timing that enables the materials to avoid the excessive thermal expansion or unequal thermal expansion that may occur among the materials of the semiconductor or packaging being serviced by the thermal solution. Once the component or packaging is brought up into the normal operating range, it can be safely started and brought to a useful operational state.

Considering the warm-up or heat-up embodiments introduced above, the balance of this disclosure and terms used should be viewed in a light that also considers the design option for such warm-up or heat-up. Thus, where terms such as cooling channel, cooling chamber volume, and cooling port are used, for example, such terms could also be considered as a thermal control channel, a thermal control volume, or a thermal control port, respectively. A person of skill would understand that heat flux or heat transfer would go in a different direction, but the design concepts are similar and can be successfully employed in the various embodiments.

In some embodiments, a cooling channel is a liquid cooling channel, and a liquid may flow through the liquid cooling channel. In some embodiments, the liquid may comprise a water and/or glycol (e.g., propylene glycol, ethylene glycol, and mixtures thereof).

As described below, coolant fluid flowing through a cold plate may be used to control the temperature of semiconductor devices. The fluid flowing across the surface of the semiconductor device absorbs heat and conducts heat away from the semiconductor device.

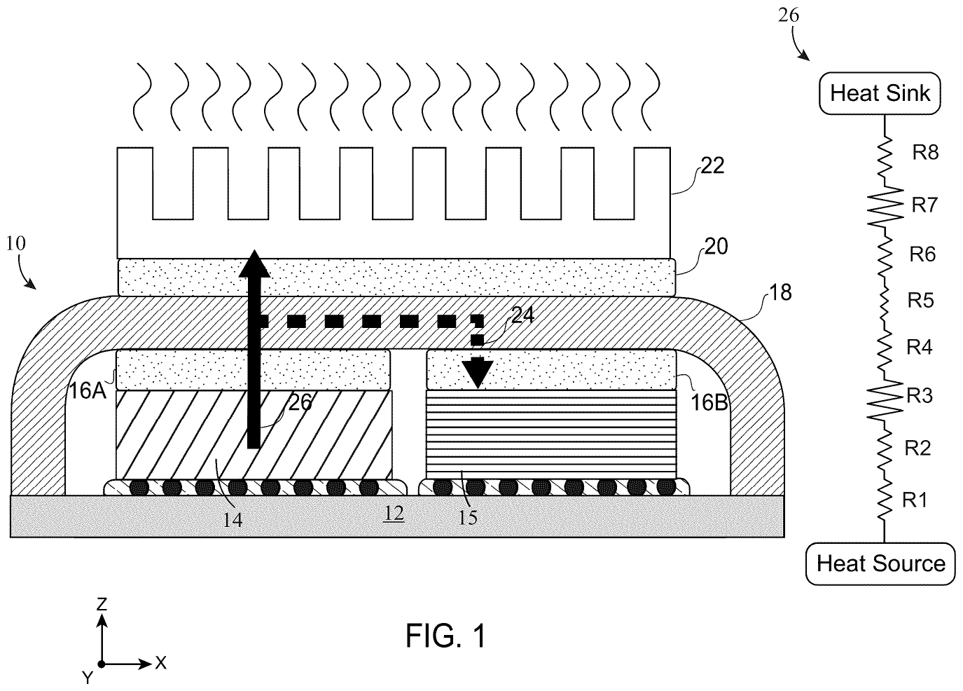

FIG. 1 is a schematic side view of a device package 10 and a heat sink 22 attached to the device package 10. The device package 10 typically includes a package substrate 12, a first device 14, a device stack 15, a heat spreader 18, and first TIM layers 16A, 16B thermally coupling the first device 14 and the device stack 15 to the heat spreader 18. The device package 10 is thermally coupled to the heat sink 22 through a second TIM layer 20. The TIM layers 16A, 16B, 20 facilitate thermal contact between components in the device package 10 and between the device package 10 and the heat sink 22.

As heat flux density increases with increasing power density in advanced semiconductor devices, the cumulative thermal resistance of the system illustrated in FIG. 1 is increasingly problematic as heat cannot be dissipated quickly enough to allow semiconductor devices to run at optimal power. Consequently, the energy efficiency of semiconductor devices is reduced. Furthermore, heat is transferred between semiconductor devices within the device package 10, as shown with heat transfer path 24 (illustrated as a dashed line), where heat may be undesirably transferred from the first device 14 having a high heat flux, such as a central processing unit (CPU) or a graphical processing unit (GPU), to the device stack 15 having low heat flux, such as memory, through the heat spreader 18.

For example, as shown in FIG. 1, each device package component and the respective interfacial boundaries therebetween have a corresponding thermal resistance that forms heat transfer path 26 (illustrated by arrow 26 in FIG. 1). The right-hand side of FIG. 1 illustrates the heat transfer path 26 as a series of thermal resistances R1-R8 between a heat source and a heat sink. Here, R1 is the thermal resistance of the bulk semiconductor material of the first device 14. R3 and R7 are the thermal resistances of the first TIM layers 16A, 16B and the second TIM layer 20, respectively. R5 is the thermal resistance of the heat spreader 18. R2, R4, R6, and R8 represent the thermal resistance at the interfacial region of the components (e.g., contact resistances). In a typical cooling system, R3 and R7 may account for 80% or more of the cumulative thermal resistance of the heat transfer path 26, and R5 may account for 5% or more. R1 of the first device 14 and R2, R4, R6, and R8 of the interfaces account for the remaining cumulative thermal resistance. Accordingly, embodiments described herein provide for integrated cooling assemblies embedded within a device package. The embedded cooling assemblies shorten the thermal resistance path between a semiconductor device and a heat sink and reduce thermal communication between semiconductor devices disposed in the same device package, such as described in relation to the figures below.

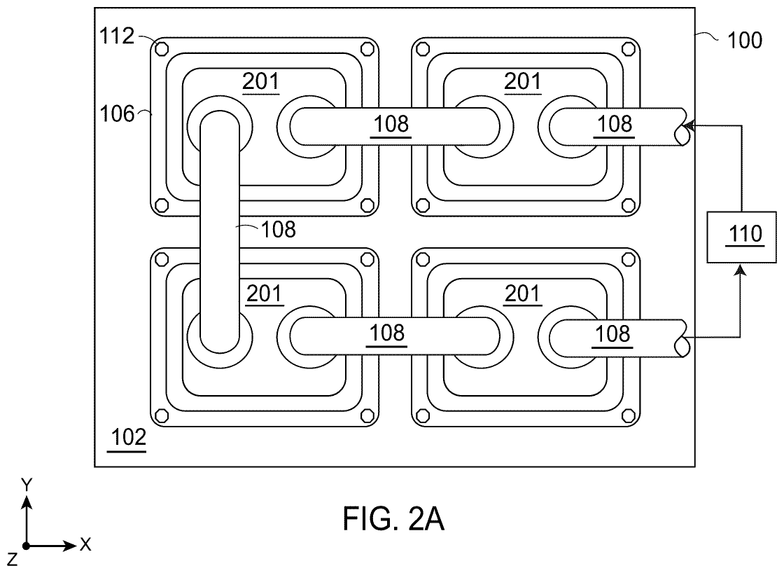

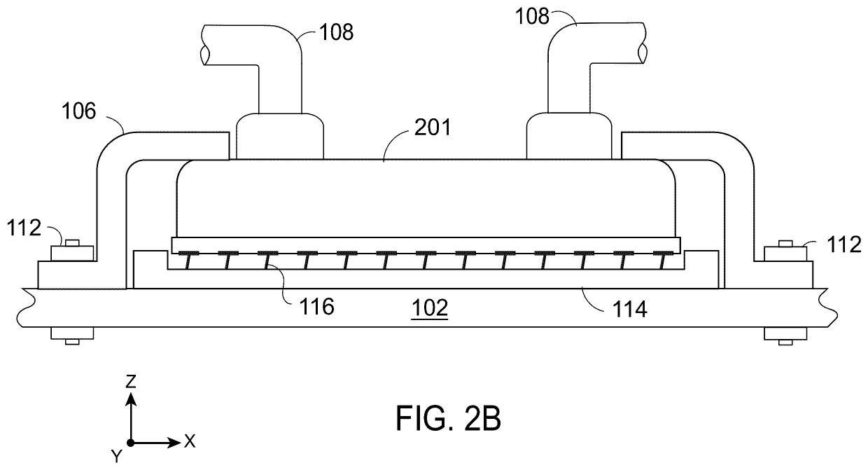

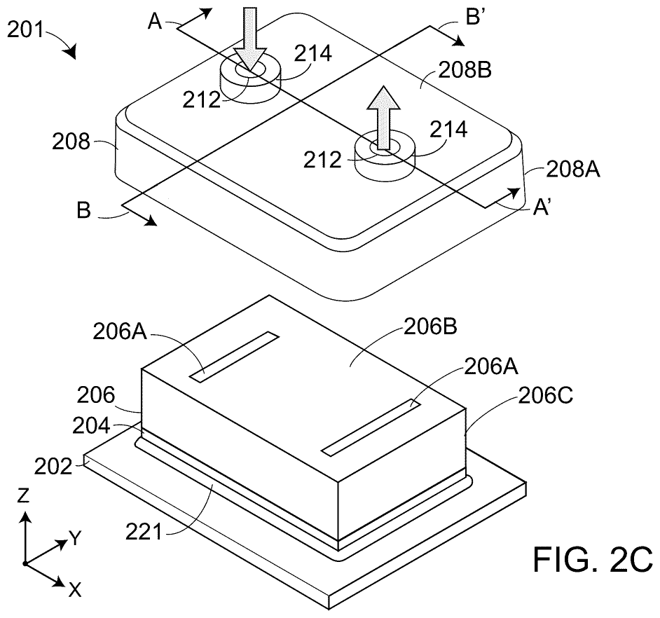

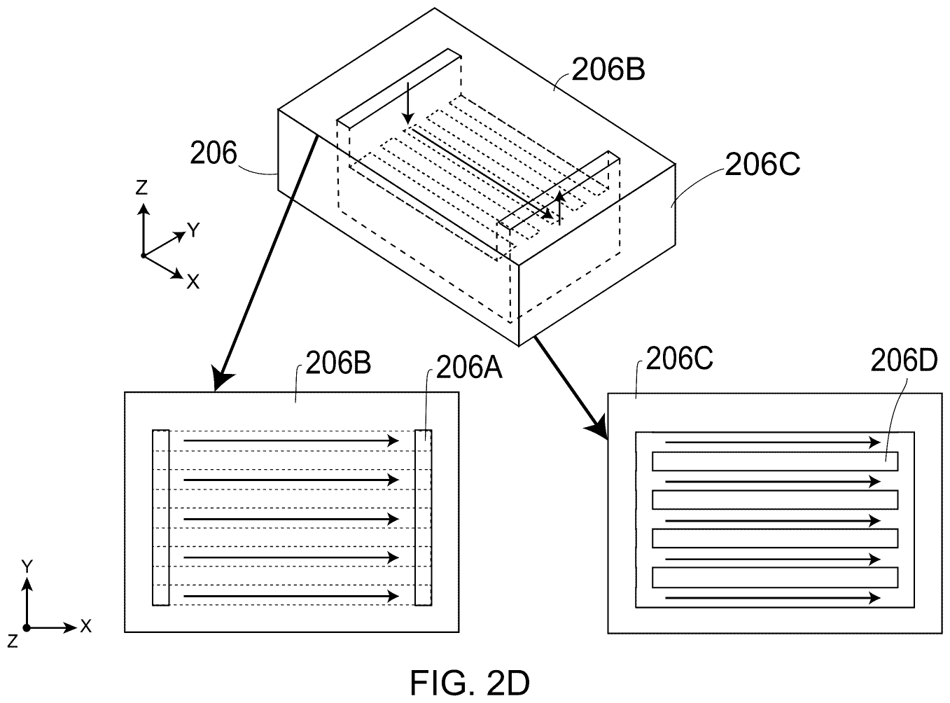

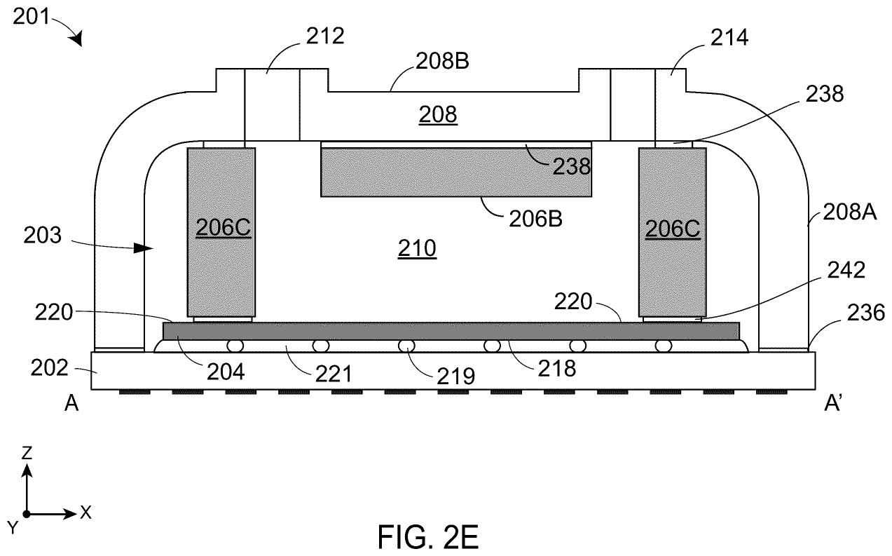

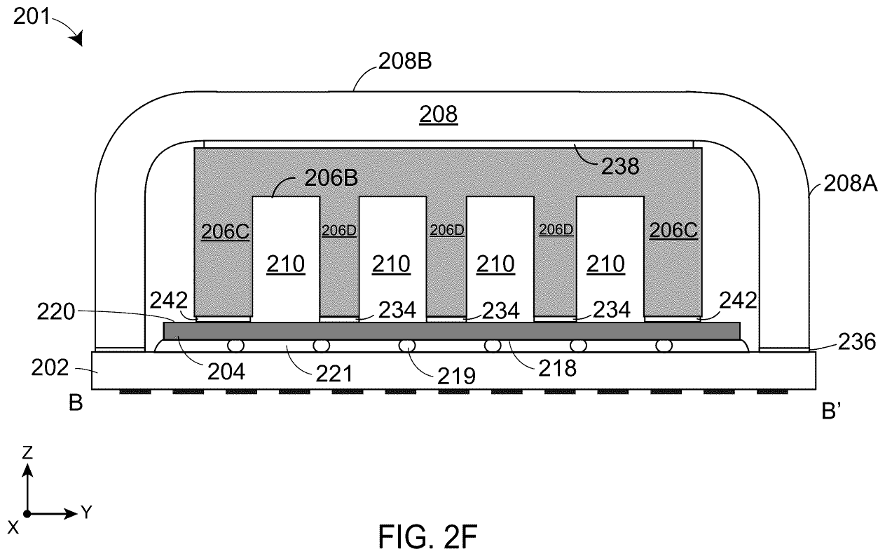

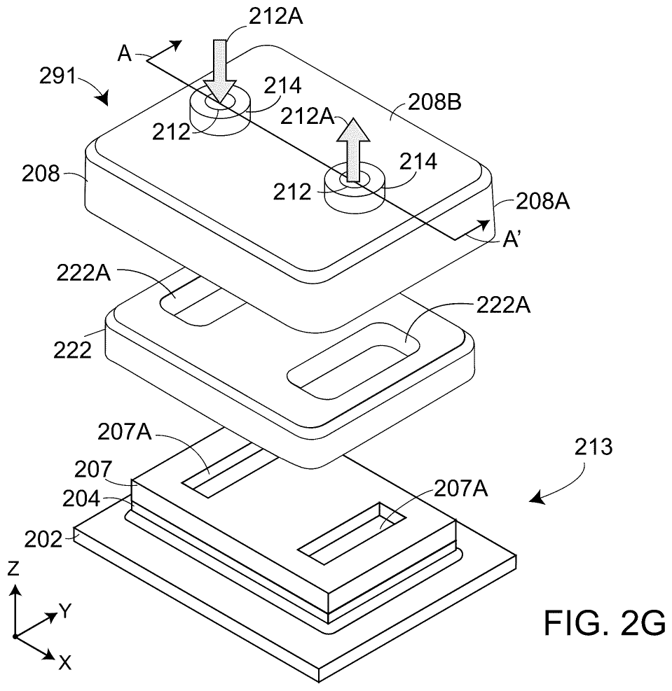

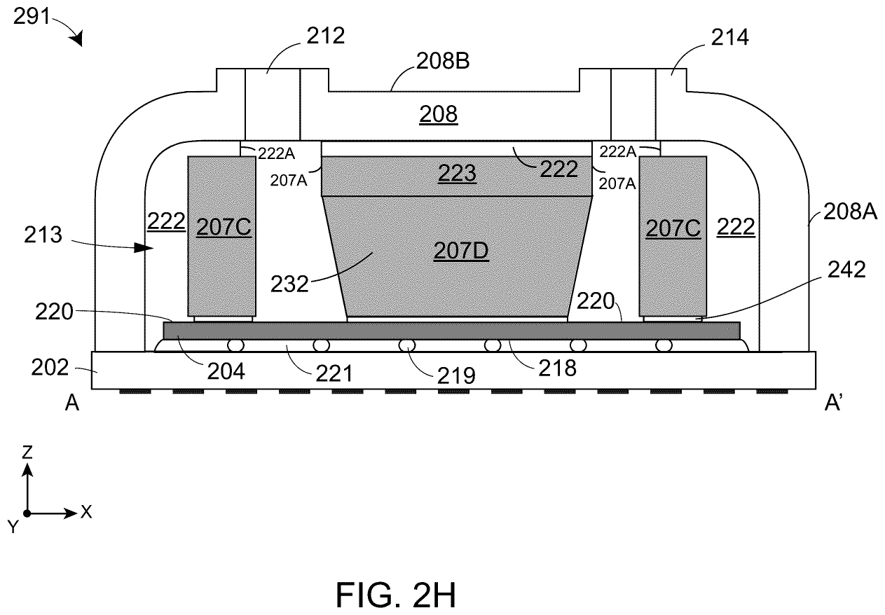

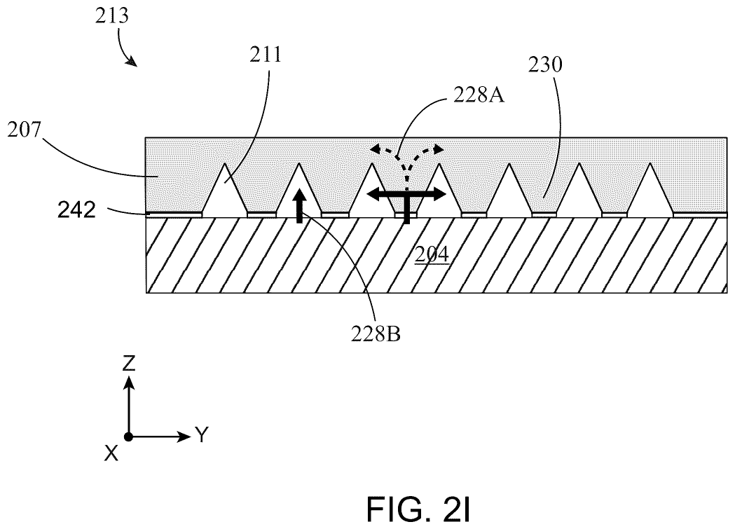

FIG. 2A is a schematic plan view of an example of a system panel 100, in accordance with embodiments of the present disclosure. Generally, the system panel 100 includes a printed circuit board (PCB) 102, a plurality of device packages 201 mounted to the PCB 102, and a plurality of coolant lines 108 fluidly coupling each of the device packages 201 to a coolant source 110. It is contemplated that coolant fluid may be delivered to each of the device packages 201 in any desired fluid phase, e.g., liquid, vapor, gas, or combinations thereof, and may flow out from each device package 201 in the same phase or a different phase. In some embodiments, the coolant fluid is delivered to the device packages 201 and returned therefrom as a liquid, whereby the coolant source 110 may comprise a heat exchanger or chiller to maintain the coolant fluid at a desired temperature. In other embodiments, the coolant fluid may be delivered to the device packages 201 as a liquid, vaporized to a vapor within the device packages 201, and returned to the coolant source 110 as a vapor. In those embodiments, the device packages 201 may be fluidly coupled to the coolant source 110 in parallel, and the coolant source 110 may include or further include a compressor (not shown) for condensing the received vapor to a liquid form.

FIG. 2B is a schematic partial sectional side view of a portion of the system panel 100 of FIG. 2A. As shown, each device package 201 is fluidly coupled to the plurality of coolant lines 108 and is disposed in a socket 114 of the PCB 102 and connected thereto using a plurality of pins 116, or by other suitable connection methods, such as solder bumps (not shown). The device package 201 may be seated in the socket 114 and secured to the PCB 102 using a mounting frame 106 and a plurality of fasteners 112, e.g., compression screws, collectively configured to exert a relatively uniform downward force on the upward facing edges of the device package 201. The uniform downward force ensures proper pin contact between the device package 201 and the socket 114.

FIG. 2C is a schematic exploded isometric view of an example device package 201, in accordance with embodiments of the disclosure. FIG. 2D is a schematic isometric, top, and bottom view of the cold plate in FIG. 2C. FIG. 2E is a schematic sectional view of the device package 201 taken along line A-A′ of FIG. 2C. FIG. 2F is a schematic sectional view of the device package 201 taken along line B-B′ of FIG. 2C. Generally, the device package 201 includes a substrate (e.g., package substrate 202), an integrated cooling assembly 203 disposed on the package substrate 202, and a cover (e.g., package cover 208) disposed on a peripheral portion of the package substrate 202. The package cover 208 extends over the integrated cooling assembly 203 so that the integrated cooling assembly 203 is disposed between the package substrate 202 and the package cover 208. The cover (e.g., package cover 208) may be made from or include a metal material, such as aluminum and/or copper, metal alloys, etc. The integrated cooling assembly 203 typically includes a semiconductor device 204 and a cold plate 206 attached to the semiconductor device 204. As shown, the device package 201 further includes an adhesive 238 that forms a coolant impermeable barrier between the package cover 208 to the integrated cooling assembly 203. Although the lateral dimensions (or footprint) of the cold plate 206 are shown to be the same or similar to the lateral dimensions (or footprint) of the semiconductor device 204, the footprint of the cold plate 206 may be smaller or larger in one or both directions when compared to the footprint of the semiconductor device 204. Coolant is delivered to the integrated cooling assembly 203 via inlet/outlet openings 212 in the package cover 208 and corresponding openings formed through the adhesive 238. In some embodiments, the device package 201 may further include a support member (not shown) attached to the integrated cooling assembly 203. It is contemplated that the device package 201 or any device package described in relation to embodiments in the present disclosure can be used in any one or combination of features of the device package described in relation to other figures herein.

Generally, the package substrate 202 includes a rigid material, such as an epoxy or resin-based laminate, that supports the integrated cooling assembly 203 and the package cover 208. The package substrate 202 may include conductive features disposed in or on the rigid material that electrically couple the integrated cooling assembly 203 to a system panel, such as the PCB 102.

The integrated cooling assembly 203 typically includes a semiconductor device, here a semiconductor portion 204 comprising a semiconductor device, and a cold plate 206 bonded to the semiconductor portion 204. In some embodiments, semiconductor portion 204 comprises a semiconductor device disposed in a molding material. Here, the device (e.g., semiconductor portion 204) includes an active side 218 that includes device components, e.g., transistors, resistors, and capacitors, formed thereon or therein, and a non-active side, here the device (e.g., semiconductor portion 204) backside 220, opposite the active side 218. As shown, the active side 218 is positioned adjacent to and facing towards the package substrate 202. The active side 218 may be electrically connected to the package substrate 202 by use of conductive bumps 219, which are encapsulated by an underfill layer 221 disposed between the semiconductor portion 204 and the package substrate 202. The underfill layer 221 may comprise a cured polymer resin or epoxy, which provides mechanical support to the conductive bumps 219 and protects against thermal fatigue. The cold plate 206 may be disposed on the package substrate 202 with the semiconductor portion 204 attached to the package substrate 202. For example, the semiconductor portion 204 may be disposed between the cold plate 206 and the package substrate 202.

As illustrated in FIG. 2D, the cold plate 206 comprises a base surface 206B, a side wall 206C, and cavity dividers 206D, all of which may be formed of metal material. The base surface 206B faces the semiconductor portion 204 and an opposite second surface faces the package cover 208. The base surface 206B and the second surface are opposite surfaces of a top portion of the cold plate 206. Inlet and outlet openings 206A are formed through the cold plate 206 by extending between the base surface and the opposite second surface. The side wall 206C extends downwardly from sides of the base surface 206B to the semiconductor portion 204. The base surface 206B, the side wall 206C, and the semiconductor portion 204 may form an enclosed volume defining the coolant channel 210 (i.e., a single coolant volume within which plural cavity coolant channels may be disposed, as discussed in more detail below). The cavity dividers 206D extend downwardly from the first side of the base surface 206B towards the semiconductor device (e.g., semiconductor portion 204, as shown in FIG. 2F). As discussed in more detail below, in some embodiments, the cavity dividers 206D may extend entirely to the semiconductor device such that lower surfaces of the cavity dividers 206D are attached to the semiconductor device. Alternatively, in some embodiments, the cavity dividers 206D may be spaced apart from the semiconductor device such that coolant fluid may flow between the cavity dividers 206D and the semiconductor device.

The cavity dividers 206D may extend laterally between the inlet opening 206A and the outlet opening 206A (e.g., as shown in FIG. 2D). Here, the cavity dividers 206D are longitudinal fins with a rectangular cross-section in the X-Y plane. In other embodiments, rows of metal posts (not shown) replace the cavity dividers 206D. The rows of metal posts may be arranged with a predetermined spacing therebetween in order that coolant fluid may flow between the metal posts. Such embodiments increase the exposed surface area of the cold plate 206, which further increases heat transfer efficiency. The metal posts may comprise, for example, aluminum or copper. The metal posts may have a cylindrical or rectangular cross-section.

The cavity dividers 206D are spaced apart from each other to define plural cavity coolant channels therebetween. In such embodiments, the cavity dividers 206D direct coolant fluid between the openings 206A through the cavity coolant channels. One or more coolant chamber volumes and/or coolant channels may extend between a single inlet opening and a single outlet opening of the cold plate 206, such that the coolant chamber volume(s) and/or coolant channel(s) share the same inlet and outlet openings.

In embodiments having plural coolant chamber volumes and/or plural coolant channels, each coolant chamber volume and/or coolant channel may be connected between a separate inlet opening and a separate outlet opening. In such embodiments, coolant fluid may be directed to the separate inlet openings and from the separate outlet openings using a manifold disposed above the openings in the Z-axis direction. In some embodiments, a gasket may be used to seal a gap between the manifold and the cold plate inlet/outlet openings. A gasket may be made of rubber (e.g., neoprene, nitrile, ethylene propylene diene monomer, or silicon rubber) or similar such material. For example, a gasket may be an o-ring. A gasket may be attached between a lower surface of the manifold and an upper surface of the cold plate facing the manifold using an adhesive. A gasket may provide a water tight seal to direct coolant fluid from the manifold into the one or more cold plate inlet/outlet openings while preventing coolant fluid from leaking onto exterior surfaces of the integrated cooling assembly 203. In some embodiments, the manifold is attached to one or more cold plates using one or more corresponding gaskets.

Although FIG. 2D and other figures of this disclosure may show examples with a particular number of channels (e.g., five channels in FIG. 2D), any suitable number of channels may be formed (e.g., 2, 3, 4, 6 or more channels) in other embodiments. Although FIG. 2F and other figures of this disclosure may show examples with a particular cross-sectional channel shape (e.g., coolant channel 210 having a rectangular cross-sectional shape in the Z-Y plane in FIG. 2F), any suitable cross-sectional shape that allows fluid to flow therethrough (e.g., triangular, rectangular, square, hexagonal, or circular cross-sections) may be used in other embodiments. It is contemplated that the cold plate 206 or any cold plate described in relation to embodiments in the present disclosure can be used in any one or combination of features of the cold plates described in relation to other figures herein.

A “cavity divider” may be taken to be a structure (e.g., post) formed for the purpose of dividing an enclosed volume into at least two separate volumes between which fluid may flow (e.g., channels, compartments, or sub-volumes).

A “side wall” may be taken to be a singular structure of a wall around or extending from the sides of an object. For example, the embodiments of this disclosure may show a side wall as a single wall comprising four sides.

In FIG. 2D, the left side view of the cold plate 206 is a top view of the cold plate 206, and the right side view of the cold plate 206 is a bottom view of the cold plate 206. As shown in FIG. 2D, fluid flows into the cold plate 206 through an inlet opening 206A, through the cavity coolant channels defined by the cavity dividers 206D, and exits out of the cold plate 206 through an outlet opening 206A. Here, the inlet opening 206A is on the left side of the cold plate 206 and the outlet opening 206A is on the right side of the cold plate, such that coolant fluid flows from the left side to the right side of the coolant channel 210. It will be understood that the openings may be reversed such that coolant fluid flows from the right side to the left side of the coolant channel 210.

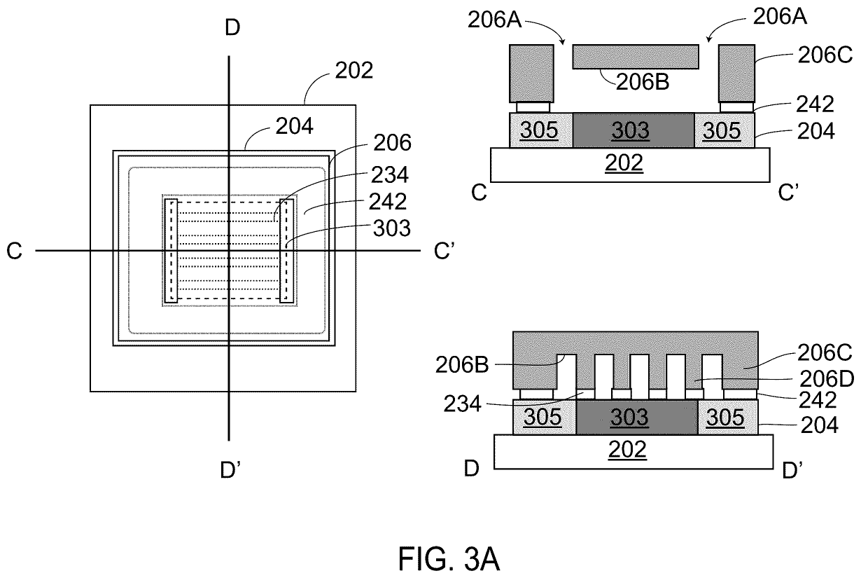

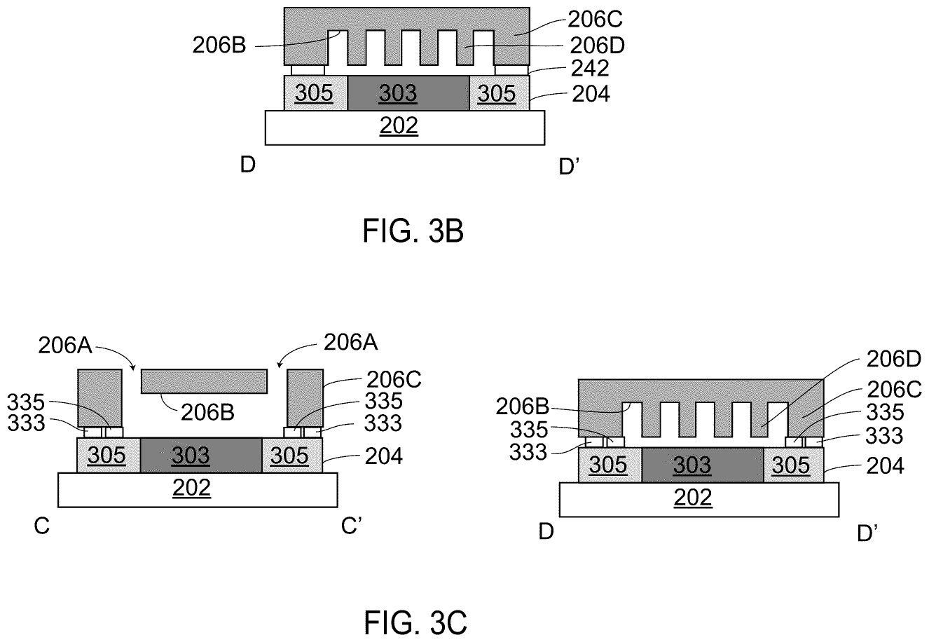

In the embodiment shown in FIGS. 2E and 2F, a top surface of the cold plate 206 opposite the base surface 206B (e.g., the opposite second surface) is attached to the cover 208 using adhesive 238. A bottom surface of the side wall 206C is attached to the backside of the semiconductor portion 204 using adhesive 242. As shown in FIG. 2F, the cavity dividers 206D are attached to a surface of the semiconductor portion 204 or the semiconductor device using an adhesive 234. The adhesive 234 may be formed of a polymer or epoxy molding material, or a compliant adhesive layer, such as a thermal interface material (TIM) layer. In some embodiments, the adhesive 234 may comprise thermally conductive particles. Heat from the semiconductor device may be transferred to the cold plate 206 through the adhesive 234. In some embodiments, a non-adhesive material may be used instead of an adhesive 234, e.g., pressed between the cavity dividers 206D (e.g., fins) and the semiconductor portion 204 (e.g., die). For example, a non-adhesive material may be a polymer. In some embodiments, the adhesive 234 or non-adhesive material may be applied on one side and pressed from the other side (e.g., adhesive or non-adhesive material applied to cavity dividers 206D and pressed from the semiconductor portion 204, or applied to semiconductor portion 204 and pressed from the cavity dividers 206D). In other embodiments, for example, as discussed in more detail below, with reference to FIGS. 3B and 3C, the cavity dividers 206D may be spaced apart from the semiconductor portion 204 or semiconductor device 303.

Here, coolant is circulated through the coolant channel 210 through openings disposed through the cold plate 206, shown here as openings 206A. The openings 206A are in fluid communication with the inlet/outlet openings 212 of the package cover 208 through openings formed in the adhesive 238 disposed therebetween.

With reference to FIGS. 2E and 2F, the cold plate 206 is attached to the backside 220 of the semiconductor portion 204. The cold plate 206 may be attached to the backside 220 of the semiconductor portion 204 using adhesive, such that the cold plate 206 and the backside 220 of the semiconductor portion 204 are in direct thermal contact through the adhesive. The package cover 208 generally comprises one or more vertical or sloped sidewall portions 208A and the lateral portion 208B that spans and connects the sidewall portions 208A. The sidewall portions 208A may extend upwardly from a peripheral surface of the package substrate 202 to surround the semiconductor portion 204 and the cold plate 206 disposed thereon. The lateral portion 208B is disposed over the cold plate 206 and is typically spaced apart from the cold plate 206 by a gap corresponding to the thickness of the adhesive 238. Coolant is circulated through the coolant channel 210 through the inlet/outlet openings 212 formed through the lateral portion 208B.

Typically, the package cover 208 is formed of semi-rigid or rigid material so that at least a portion of the downward force exerted on the package cover 208 by the mounting frame 106 (FIG. 2B) is transferred to the supporting surface of the package substrate 202 and not transferred to the cold plate 206 and the semiconductor portion 204 therebelow. In some embodiments, the package cover 208 is formed of a thermally conductive metal, such as aluminum or copper. In some embodiments, the package cover 208 functions as a heat spreader that redistributes heat from one or more electronic components within a multi-component device package. In some embodiments, the package cover 208 and/or a manifold may consist of or comprise a thermally insulating material or materials. In such embodiments, the package cover 208 and/or a manifold functions as a thermal insulator to retain heat or cold. In some embodiments, the package cover 208 and/or a manifold is insulating to minimize or reduce heat flow between components (e.g., dies, die stacks, device packages, etc.). For example, the package cover 208 and/or a manifold may minimize or reduce heat flow between a first die and a second die. In another example, the package cover 208 and/or a manifold may minimize or reduce heat flow between a first die stack and a second die stack. In another example, the package cover 208 and/or a manifold may minimize or reduce heat flow between a first device package and a second device package. In another example, the package cover 208 and/or a manifold may minimize or reduce heat flow between a first die and a first die stack. In another example, the package cover 208 and/or a manifold may minimize or reduce heat flow between a first die of a first device package and a second device package.

The adhesive 238 forms an impermeable barrier between the integrated cooling assembly 203 and the package cover 208. Further, the adhesive 242 forms an impermeable barrier between the cold plate 206 and the semiconductor portion 204 that prevents coolant from reaching the active side 218 of the device (e.g., semiconductor portion 204) and causing damage thereto. In some embodiments, the adhesive 238 may be disposed between only the backside surface of the cold plate 206 and the portion of the package cover 208 disposed thereover. In other embodiments, the adhesive 238 is formed from a molding compound, e.g., a thermoset resin, that when polymerized, forms a hermetic seal between the package cover 208 and the cold plate 206. Here, coolant is delivered to the cold plate 206 through openings disposed through the adhesive 238. As shown, the openings disposed through the adhesive 238 are respectively in registration and fluid communication with the inlet/outlet openings 212 of the package cover 208 thereabove and the inlet/outlet openings 206A in the cold plate 206 therebelow. Typically, coolant lines are attached to the device package 201 by use of connector features formed in the package cover 208, such as threads formed in the sidewalls of the inlet/outlet openings 212 and/or protruding features 214 that surround the inlet/outlet openings 212 and extend upwardly from the surface of the lateral portion 208B.

In some embodiments, the adhesive 238 extends upwardly from the package substrate 202 to encapsulate and/or surround at least a portion of the semiconductor portion 204. Beneficially, the adhesive 238 may provide mechanical support that improves system reliability and extends the useful lifetime of the device package 201. For example, the adhesive 238 may reduce mechanical stresses that can weaken interfacial bonds and/or electrical connections between electrical components of the device package 201, such as stresses caused by vibrations, mechanical and thermal shocks, and/or fatigue caused by repeated thermal cycles. In some embodiments, the adhesive 238 may be a thermally conductive material, such as a polymer or epoxy having one or more thermally conductive additives, such as silver and/or graphite.

FIG. 2G is a schematic exploded isometric view of the device package in FIG. 2B. FIG. 2G shows a device package 291 which is similar to the device package 201 of FIG. 2C, except it includes a sealing material layer 222 and cold plate 207. For example, the sealing material layer 222 of the device package 291 as shown in FIG. 2G-2H may be used in place of the adhesive 238 and adhesive 236 as shown in the device package 201 in FIGS. 2E-2F and cold plate 207 as shown in FIG. 2G-2I may be used in place of cold plate 206 in FIGS. 2C-2E. A description of corresponding (e.g., same or similar) components in the device package 201 of FIG. 2G and the device package 291 of FIG. 2C can be found in either and/or both of the description relevant to FIGS. 2G and 2C. For example, cold plate 206 and cold plate 207 may have similar or corresponding components (e.g., side wall 207C and cavity divider 207D of the cold plate 207, may be similar to side wall 206C and cavity divider 206D of the cold plate 206, etc.), and description of similar or corresponding components may be applied to either cold plate 206, cold plate 207, or any suitable cold plate such as those mentioned as embodiments of the present disclosure. The description of similar or different components or features of the device package 291 in FIGS. 2G, 2H, and 2I may be applied to the device package 201 of FIGS. 2C, 2E, and 2F, or any other suitable device package, components, or features described throughout this disclosure. For example, a cold plate 206 of FIG. 2C may use a channel 211 with a triangular cross section in place of a channel 210 with a rectangular cross section. For example, a device package 201 may use a sealing material layer 222 in place of adhesive 238 and 242. As shown, the device package 291 further includes a sealing material layer 222 that forms a coolant fluid impermeable barrier between the package cover 208 and the integrated cooling assembly 213 that prevents leaking of the coolant fluid outside of the cooling assembly and prevents coolant fluid from reaching an active side 218 of the semiconductor device 204 and causing damage thereto. In some embodiments, the sealing material layer 222 comprises an adhesive material that reliably attaches the package cover 208 to the integrated cooling assembly 213. In some embodiments, the sealing material layer 222 comprises a polymer or epoxy material that extends upwardly from the package substrate 202 to encapsulate and/or surround at least a portion of the semiconductor device 204. In some embodiments, the sealing material layer 222 may also comprise conductive material, e.g., solder. In other embodiments, the sealing material layer 222 is formed from a molding compound, e.g., a thermoset resin, that when polymerized, forms a hermetic seal between the package cover 208 and the cold plate 207. Here, the coolant fluid is delivered to the cold plate 207 through openings 222A disposed through the sealing material layer 222. As shown, the openings 222A are respectively in registration and fluid communication with inlet and outlet openings 212 of the package cover 208 thereabove and inlet and outlet openings 207A in the cold plate 207 therebelow.

It will be understood that the openings are shown in a section view. The openings may have any cross-sectional shape that allows fluid to flow therethrough (e.g., triangular, rectangular, square, hexagonal or circular cross-sections). For example, the inlet and outlet openings 207A of the cold plate 207 may form an elongated shape extending from one side of the cold plate 207 to another side of the cold plate 207. For example, the inlet and outlet openings 207A may form any shape having a length greater than a width in the X-Y plane (e.g., a rectangular or a trapezoidal shape). A shape in the X-Y plane of the openings 222A disposed through the sealing material layer 222 may be substantially the same as the shape of the inlet and outlet openings 207A of the cold plate 207 in the same place. Furthermore, it will be understood that all references to an opening throughout the present disclosure refer to an opening defined by a sidewall (e.g., opening sidewall).

FIG. 2H is a schematic sectional view of an example device package, in accordance with embodiments of the present disclosure, that may be used with the system panel. FIG. 2H is a schematic sectional view in the X-Z plane of the device package 291 taken adjacent to, along line A-A′ of FIG. 2G. Unlike the view of FIG. 2E which shows a cross section of the cold plate 206 at a coolant channel 210, the sectional view in FIG. 2H shows a cross section of the cold plate 207 at a cavity divider 207D. As illustrated in FIG. 2H, the semiconductor device 204 includes the active side 218 that includes device components, e.g., transistors, resistors, and capacitors, formed thereon or therein, and a non-active side, here the semiconductor device backside 220, opposite the active side 218. As shown, the active side 218 is positioned adjacent to and facing towards the package substrate 202. The active side 218 may be electrically connected to the package substrate 202 by use of conductive bumps 219, which are encapsulated by a first underfill layer 221 disposed between the semiconductor device 204 and the package substrate 202. The first underfill layer 221 may comprise a cured polymer resin or epoxy, which provides mechanical support to the conductive bumps 219 and protects against thermal fatigue. In some embodiments, the active side 218 may be electrically connected to another package substrate, another active die, or another passive die (e.g., interposer) using hybrid bonding or conductive bumps 219. The cold plate 207 may be disposed above the package substrate 202 with the semiconductor device 204 disposed therebetween. For example, the semiconductor device 204 (and the first underfill layer 221) may be disposed between the cold plate 207 and the package substrate 202. In some embodiments, the cold plate 207 may be disposed directly on the package substrate 202.

Here, the cold plate 207 comprises a top portion 223 and a sidewall or side wall 207C (e.g., a perimeter sidewall defining a perimeter of the cold plate 207) extending downwardly from the top portion 223 to the backside 220 of the semiconductor device 204. The top portion 223, the perimeter sidewall (e.g., side wall 207C), and the backside 220 of the semiconductor device 204 collectively define a coolant channel 210 therebetween. The cold plate 207 comprises cavity dividers 207D extending downwardly from the top portion 223 towards the backside 220 of the semiconductor device 204. The cavity dividers 207D may alternatively be referred to as support features 207D, which provide structural support to the integrated cooling assembly 213. The cavity dividers 207D may extend laterally and in parallel between an inlet opening 207A of the cold plate 207 and an outlet opening 207A of the cold plate 207 to define coolant channels 210 therebetween. It should be appreciated that, the cold plate 207 may comprise one cavity divider 207D which forms two coolant channels (e.g., one coolant channel on either side of the cavity divider 207D) by means of the cavity divider 207D and portions of the perimeter sidewall (e.g., side wall 207C). More specifically, coolant channels 211 may be formed between the cavity divider 207D and a portion of the perimeter sidewall (e.g., side wall 207C) extending parallel to the cavity divider 207D. Alternatively, in other embodiments, the cold plate 207 may comprise plural cavity dividers 207D, for example two cavity dividers, five cavity dividers, or six cavity dividers (as illustrated in FIG. 2I). In such examples, the cold plate 207 comprises more than two coolant channels 211, for example three coolant channels, four coolant channels, seven coolant channels, or more, defined between the cavity dividers 207D and/or the cavity divider(s) 207D and the perimeter sidewall (e.g., side wall 207C).

The cavity dividers 207D comprise cavity sidewalls 232 which form surfaces of corresponding coolant channels 210. In embodiments where plural cavity dividers 207D extend in parallel to each other, cavity sidewalls 232 of adjacent cavity dividers 207D are opposite (e.g., facing) each other. In embodiments comprising a single cavity divider 207D, a first cavity sidewall may be opposite (e.g., face) a first portion of the perimeter sidewall (e.g., side wall 207C) extending parallel to and facing the first cavity sidewall. A second cavity sidewall may be opposite (e.g., face) a second portion of the perimeter sidewall (e.g., side wall 207C) extending parallel to and facing the second cavity sidewall. The first portion of the perimeter sidewall (e.g., side wall 207C) may be an opposite side of the cold plate 207 to the second portion of the perimeter sidewall (e.g., side wall 207C). For example, in embodiments where the cold plate 207 is rectangular, first and second opposing sides of the rectangular cold plate 207 form the first and second portions of the perimeter sidewall (e.g., side wall 207C).

The cavity dividers 207D (e.g., cavity divider 230 as shown in FIG. 2I) may be continuous cavity dividers which extend continuously (e.g., in the X-axis direction) between the inlet opening 207A and the outlet opening 207A of the cold plate 207.

FIG. 2I is a schematic sectional view of an integrated cooling assembly of the device package, in accordance with embodiments of the present disclosure.

With reference to FIG. 2H, coolant channels 211 may be defined by:
the backside 220 of the semiconductor device 204, which forms lower coolant channel surfaces;
portions of the perimeter sidewall (e.g., side wall 207C) extending in the Y-axis direction, which form end surfaces of the coolant channels 211;
the cavity sidewalls 232, which form inner surfaces of the coolant channels 211 in the X-axis direction; and
portions of the perimeter sidewall (e.g., side wall 207C) extending in the X-axis direction, which form outer surfaces of the coolant channels 211 in the X-axis direction.

Here, the cavity sidewalls 232 are formed at an acute angle with respect to the backside 220 of the semiconductor device 204 such that upper portions of opposing (e.g., facing) cavity sidewalls 232 meet. Therefore, the cavity sidewalls 232 and the backside 220 of the semiconductor device 204 collectively define a triangular cross-section of the coolant channel 211.

In some embodiments, the backside 220 of the semiconductor device 204 comprises a corrosion protective layer (not shown). The corrosion protective layer may be a continuous layer disposed across the entire backside 220 of the semiconductor device 204, such that the cold plate 207 is attached thereto. Beneficially, the corrosion protective layer provides a corrosion-resistant barrier layer, thus preventing undesired corrosion of the semiconductor device 204 (e.g., the semiconductor substrate material which might otherwise be in direct contact with coolant fluid flowing through a coolant chamber volume 211).

One or more coolant chamber volumes may include one or more coolant channels. The coolant channels may extend between a single inlet opening and a single outlet opening of the cold plate 207, such that the coolant chamber volume(s) and/or coolant channel(s) share the same inlet and outlet openings. In some embodiments, multiple inlet and/or outlet openings may be coupled to the coolant chamber volume(s).

In embodiments having plural coolant chamber volumes and/or plural coolant channels, each coolant chamber volume and/or coolant channel may be connected between a separate inlet opening and a separate outlet opening. In such embodiments, the coolant fluid may be directed to the separate inlet openings and from the separate outlet openings using a manifold disposed above the openings in the Z-axis direction.

In some embodiments, a height in the Z-axis direction of the coolant chamber volume(s) and or coolant channel(s) may be greater than 100 μm, 100 μm-1000 μm, or 100 μm-700 μm. A width in the Y-axis direction of the coolant chamber volume(s) and/or coolant channel(s) may be greater than 100 μm, 100 μm-1000 μm, or 100 μm-700 μm. For example, the width of the coolant chamber volume(s) and/or coolant channel(s) may be greater than the height. In some embodiments, the width of the coolant chamber volume(s) and/or coolant channel(s) may be, at the widest portion, which may be taken as a base of the triangular shape of the coolant chamber channels 211 shown in FIG. 2I, range from 0.2 mm to 5 mm. More specifically, the width of the coolant chamber volume(s) and/or coolant channel(s) may range from 0.5 to 1.5 mm. The width of the coolant chamber volume(s) and/or coolant channel(s) may also be between 1 and 5 mm.

A cross-section of the coolant chamber volume(s) and/or coolant channel(s) in the Y-Z plane is wide enough to allow for a pressure drop of 0-20 psi, 3-15 psi, or 4-10 psi.

In some embodiments, preparing a desired surface roughness of the sidewalls of the coolant chamber volume(s) and/or coolant channels may include depositing an organic layer on a photoresist layer after cold plate features have been etched to form a micro-masking layer, such as between 1 to 30 nm. The micro-masking layer may be dry etched to form the desired surface roughness, such as between 0.1 to 3.0 nm.

With reference to FIG. 2H, the cold plate 207 is attached to the backside 220 of the device 204. With reference to FIGS. 2H and 2I, described below, adhesive 242 may be disposed only on lower surfaces of the cavity dividers 207D (e.g. support features 207D) and the perimeter sidewall (e.g., side wall 207C).

FIG. 2H is a schematic sectional view in the Y-Z plane of the integrated cooling assembly 213. In FIG. 2H, the cold plate 207 comprises a patterned side that faces towards the semiconductor device 204 and an opposite side that faces towards the package cover 208 (not shown). The patterned side comprises a coolant chamber volume having plural coolant channels 211, which extend laterally between the inlet and outlet openings of the cold plate 207. Each coolant channel 211 comprises cavity sidewalls that define a corresponding coolant channel 211. Portions of the cold plate 207 between the cavity sidewalls form the support features 207D (e.g., cavity dividers 207D). The support features 207D (e.g., cavity dividers 207D) provide structural support to the integrated cooling assembly 213 and disrupt laminar fluid flow at the interface of the coolant and the device backside 220, resulting in increased heat transfer therebetween. Furthermore, by introducing plural coolant channels 211 to define separate coolant flow paths, an internal surface area of the cold plate 207 is increased, which further increases the efficiency of heat transfer.

In FIG. 2H, arrows 228A and 228B illustrate two different heat transfer paths in the integrated cooling assembly 213. A first heat transfer path illustrated by arrow 228B shows heat generated by the semiconductor device 204 transferring directly from the semiconductor material of the semiconductor device 204 to coolant fluid flowing through the cold plate 207. A second heat transfer path illustrated by arrows 228A shows heat generated by the semiconductor device 204 being transferred from semiconductor material (e.g., silicon material) of the semiconductor device 204 to adhesive 242 to the cold plate 207 structure, propagated throughout the material of the cold plate 207 structure (shown as dashed lines), and being transferring into coolant fluid flowing through the cold plate 207.

The cold plate 207 or any suitable cold plate such as those mentioned in the present disclosure (e.g., cold plate 206 of FIGS. 2C-2F, 3A-3C, etc.) may be formed of any suitable material that has sufficient structural strength to withstand the desired pressures of coolant flowing into the coolant chamber volume 211. For example, the cold plate 207 may be formed engineered materials like glass. In other examples, the cold plate 207 may be formed of a material selected from a group comprising polymers, metals, ceramics, or composites thereof. In some embodiments, the cold plate 207 may be formed of stainless steel (e.g., from a stainless steel metal sheet) or a sapphire plate.

In some embodiments, the cold plate 207 or any suitable cold plate such as those mentioned in the present disclosure (e.g., cold plate 206 of FIGS. 2C-2F, 3A-3C, etc.) may be formed of a bulk material having a substantially similar coefficient of linear thermal expansion (CTE) to the bulk material of the substrate 202 and/or the semiconductor device 204, where the CTE is a fractional change in length of the material (in the X-Y plane) per degree of temperature change. In some embodiments, the CTEs of the cold plate 207, the substrate 202, and/or the semiconductor device 204 are matched so that the CTE of the substrate 202 and/or the semiconductor device 204 is within about +/−20% or less of the CTE of the cold plate 207, such as within +/−15% or less, within +/−10% or less, or within about +/−5% or less when measured across a desired temperature range. In some embodiments, the CTEs are matched across a temperature range from about −60° C. to about 100° C. or from about −60° C. to about 175° C.

In some embodiments, the cold plate 207 or any suitable cold plate such as those mentioned in the present disclosure (e.g., cold plate 206 of FIGS. 2C-2F, 3A-3C, etc.) may be formed of a material having a substantially different CTE from the semiconductor device 204, e.g., a CTE mismatched material. In such embodiments, the cold plate 207 may be attached to the semiconductor device 204 by a compliant adhesive layer 242 or a molding material that absorbs the difference in expansion between the cold plate 207 and the semiconductor device 204 across repeated thermal cycles.

The package cover 208 shown in FIGS. 2G and 2H generally comprises one or more vertical or sloped sidewall portions 208A and a lateral portion 208B that spans and connects the sidewall portions 208A. The sidewall portions 208A may extend upwardly from a peripheral surface of the package substrate 202 to surround the device 204 and the cold plate 207 disposed thereon. The lateral portion 208B may be disposed over the cold plate 207 and is typically spaced apart from the cold plate 207 by a gap corresponding to the thickness of the sealing material layer 222. The sealing material layer 222 may be an adhesive or a gasket. In some embodiments, instead of or as well as the sealing material layer 222, a gasket may be used to seal a gap between the package cover 208 and the cold plate inlet/outlet openings. The gasket may be made of rubber (e.g., neoprene, nitrile, ethylene propylene diene monomer, or silicon rubber) or similar such material. For example, the gasket may be an o-ring. The gasket may be attached between a lower surface of the package cover 208 and an upper surface of the cold plate facing the package cover 208 using an adhesive. The gasket may provide a water tight seal to direct coolant fluid from the package cover 208 into the cold plate inlet/outlet openings while preventing coolant fluid from leaking onto exterior surfaces of the integrated cooling assembly 213. In some embodiments, the package cover 208 is attached to one or more cold plates using one or more corresponding gaskets.

Coolant is circulated through the coolant chamber volume 211 through the inlet and outlet openings 212 of the package cover 208 formed through the lateral portion 208B. The inlet and outlet openings 207A of the cold plate 207 may be in fluid communication with the inlet and outlet openings 212 of the package cover 208 through the inlet and outlet openings 222A formed in the sealing material layer 222 disposed therebetween. In certain embodiments, coolant lines 108 (FIGS. 2A-2B) may be attached to the device package 291 by use of connector features formed in the package cover 208, such as threads formed in the sidewalls of the inlet and outlet openings 212 of the package cover 208 and/or protruding features 214 that surround the inlet and outlet openings 212 and extend upwardly from a surface of the lateral portion 208B.

Typically, the package cover 208 is formed of semi-rigid or rigid material so that at least a portion of the downward force exerted on the package cover 208 by the mounting frame is transferred to a supporting surface of the package substrate 202 and not transferred to the cold plate 207 and the semiconductor device 204 therebelow. In some embodiments, the package cover 208 is formed of a thermally conductive metal, such as aluminum or copper. In such embodiments, the package cover 208 functions as a heat spreader that redistributes heat from one or more electronic components of the semiconductor device 204. In some embodiments, the package cover 208 and/or a manifold (such as the manifold discussed above, or any suitable manifold in embodiments of the present disclosure) may consist of or comprise a thermally insulating material or materials. In such embodiments, the package cover 208 and/or the manifold may function as a thermal insulator to retain heat or cold. In some embodiments, the package cover 208 and/or the manifold may be insulating to minimize or reduce the flow of thermal energy (e.g., thermal flux) between components (e.g., semiconductor devices, semiconductor device stacks, device packages, etc.). For example, the package cover 208 and/or the manifold may minimize or reduce the flow of thermal energy between a first semiconductor device and a second semiconductor device. In another example, the package cover 208 and/or a manifold may minimize or reduce the flow of thermal energy between a first semiconductor device stack and a second semiconductor device stack. In another example, the package cover 208 and/or a manifold may minimize or reduce the flow of thermal energy between a first device package and a second device package. In another example, the package cover 208 and/or the manifold may minimize or reduce the flow of thermal energy between a semiconductor device and a semiconductor device stack. In another example, the package cover 208 and/or the manifold may minimize or reduce the flow of thermal energy between a semiconductor device of a first device package and a second device package.

It should be noted that the direction in which the coolant fluid flows through the cold plate 207 may be controlled depending on the relative locations of the inlet and outlet openings. For example, the coolant fluid may flow from left to right in the device package 201 of FIG. 2H when the inlet openings 212, 222A, 207A of the package cover 208, the sealing material layer 222, and the cold plate 207, respectively, are located on the left-hand side of the device package 201 and the outlet openings 212, 222A, 207A of the package cover 208, the sealing material layer 222, and the cold plate 207, respectively, are located on the right-hand side of the device package 201. Alternatively, the coolant fluid may flow from right to left in the device package 201 illustrated in FIG. 2H when the outlet openings 212, 222A, 207A of the package cover 208, the sealing material layer 222, and the cold plate 207 are located on the left-hand side of the device package 201 and the inlet openings 212, 222A, 207A of the package cover 208, the sealing material layer 222, and the cold plate 207 are located on the right-hand side of the device package 201. Although only one set of inlet and outlet openings is shown and described here, additional inlet and outlet openings may also be provided at various locations on the package cover 208, the sealing material layer 222, and the cold plate 207.

An example flow path of the coolant fluid through the coolant chamber volume 211 may be as follows:
1. Coolant fluid enters the coolant chamber volume 211 through the inlet openings.
2. Coolant fluid flows across the inside surfaces of the cold plate 207 and absorbs heat generated by the semiconductor device 204, which has dissipated into the cold plate 207 structure. The coolant fluid may also flow directly across the backside 220 of the semiconductor device 204 to absorb heat energy directly from the semiconductor device 204. The coolant chamber volume 211 may additionally have various channels formed to direct the coolant fluid flow from inlet opening(s) to outlet opening(s) and facilitate heat extraction from the semiconductor device 204 by the coolant fluid. In some embodiments, the coolant fluid may be in direct contact with the backside 220 of the semiconductor device 204 or via one or more substrate or layers between the coolant fluid or backside 220 of the semiconductor device 204.
3. Coolant fluid exits the coolant chamber volume 211 through outlet openings.

It will be understood from the above flow path that heat may be extracted between the backside 220 of the semiconductor device 204 and the cold plate 207 through an adhesive 242 disposed between the backside 220 of the semiconductor device 204 and the cold plate 207.

FIG. 3A is a schematic top view and sectional views of an integrated cooling assembly, in accordance with some embodiments of the disclosure. The schematic top view shows a substrate 202, semiconductor portion 204, adhesive 242 and 234, and cold plate 206. The schematic sectional view taken along line C-C′ of FIG. 3A shows a coolant channel along the length of the cavity. The schematic sectional view taken along line D-D′ of FIG. 3A shows a cross section of the cavity coolant channels formed between the cavity dividers 206D themselves and between the cavity dividers 206D and the side wall 206C. The semiconductor portion 204 comprises semiconductor device 303 disposed in a molding material 305. The molding material 305 may comprise an epoxy or a polymer material. The semiconductor device 303 may be a die or chip. The side wall 206C extends downwardly from sides of the base surface 206B to the molding material 305, and the side wall 206C is attached to the molding material 305 using adhesive 242. The cavity dividers 206D extend downwardly from the base surface 206B towards the semiconductor device 303. The cavity dividers 206D are attached to the semiconductor device 303 using the adhesive 234. The cold plate 206 may conduct heat from the semiconductor device 303 through the adhesive 234. The cold plate 206 may be cooled by coolant fluid flowing through the channels. Coolant fluid may enter the cold plate 206 through the inlet opening 206A, flow through the cavity coolant channels defined by the cavity dividers 206D, and exit the cold plate 206 via the outlet opening 206A.

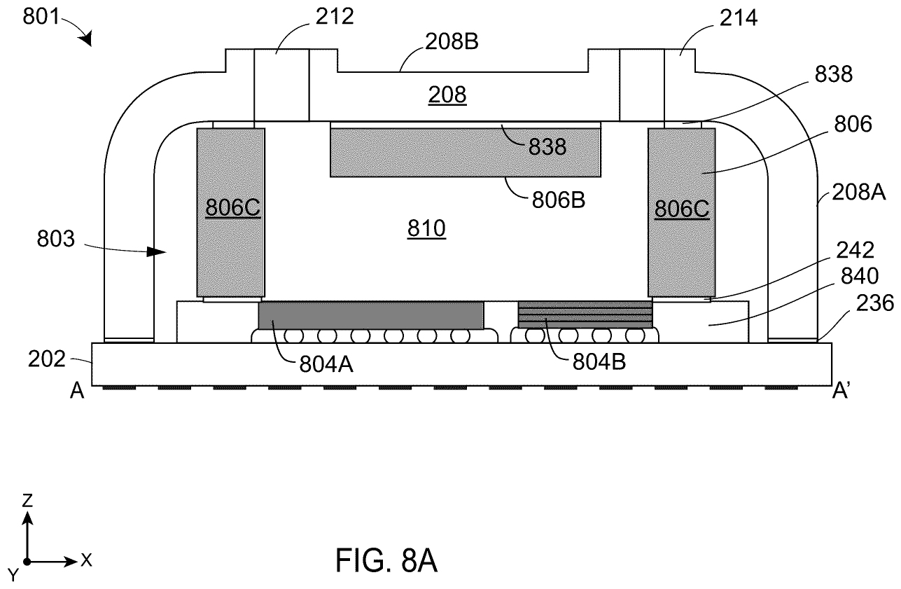

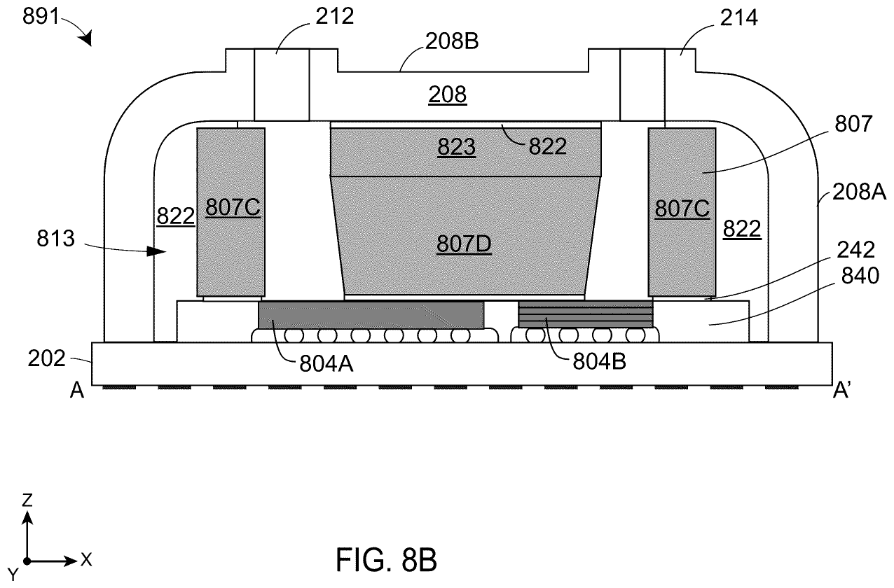

Although FIG. 3A, and other figures in the disclosure show examples with only one semiconductor device 303, it will be understood that there may be any suitable number of semiconductor devices (e.g., two or more semiconductor devices). For example, there may be one or more semiconductor devices in a plane and/or one or more stacked semiconductor devices (e.g., as shown in FIG. 8). Although FIG. 3A, and other figures in the disclosure show examples with the cold plate 206 being used, it will be understood that any suitable cold plate may be used (e.g., cold plate 207 or any other suitable cold plate such as those described in embodiments of the present disclosure) in place of the cold plate 206. In some embodiments, cold plate 207 of FIG. 2G may be used in place of cold plate 206 of FIGS. 2C-2F, 3A-3C, or any other suitable cold plate such as those described in embodiments of the present disclosure. In some embodiments, a cold plate 206 of FIGS. 2C-2F, 3A-3C, or any other suitable cold plate such as those described in embodiments of the present disclosure may be used in place of cold plate 207 of FIG. 2G.

FIGS. 3B and 3C are schematic sectional views of examples of the integrated cooling assembly of FIG. 3A. For example, both FIGS. 3B and 3C show the cavity dividers 206D separated from a surface of the semiconductor device 303 to define a gap therebetween. Lower surfaces of the cavity dividers 206D may be close enough to the semiconductor device 303 so that the fluid is retained (or primarily remains) within separate cavity coolant channels while traveling across the backside of the semiconductor device 303 (e.g., less than about 2%, or less than about 1%, or less than about 0.5%, or less than about 0.1% of the coolant fluid flow may travel from one channel to another channel of the cavity coolant channels). The lower surfaces of the cavity dividers 206D may be spaced apart from the backside of the semiconductor device 303 to define a gap of less than about 100 microns, or less than about 150 microns, or less than about 200 microns. FIG. 3C shows an adhesive 333 and a shim 335. The adhesive 333 may be similar to adhesive 242 except it is disposed laterally adjacent to the shim 335 (e.g., between the lower surfaces of the cavity dividers 206D and the backside of the semiconductor device 303 or the molding material 305. The shim 335 may comprise a layer of any suitable material (e.g., metal material, molding material, etc.) of a particular thickness which may be used to ensure a spacing between two adjacent surfaces to be at least a thickness of the shim. The shim 335 may separate the cold plate 206 from the surface of the molding material 305 by a distance corresponding to the gap. Although FIG. 3C and other figures in the disclosure may show examples of a shim and adjacent adhesive in a particular configuration, the placement of the shim and the adhesive may be in any suitable arrangement in other embodiments (e.g., shim may be laterally between adhesives or disposed in adhesive, placement of shim and adhesive may be switched) in other embodiments.

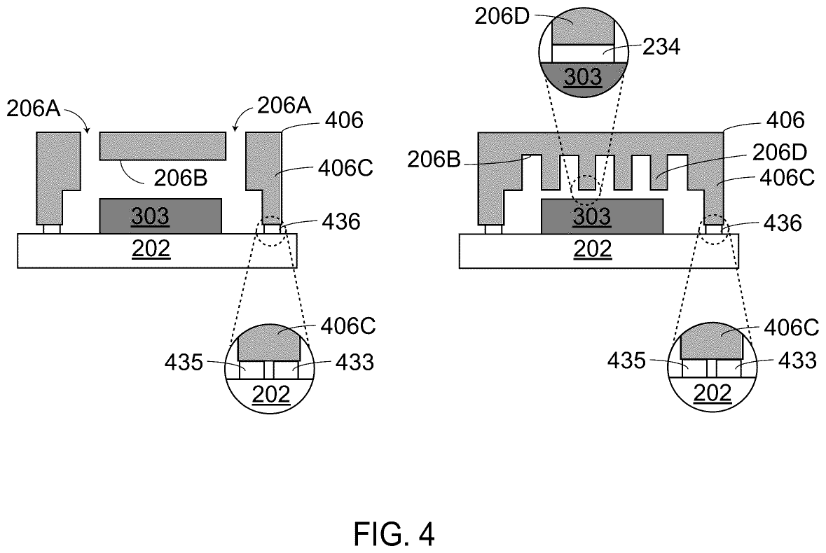

FIG. 4 is schematic sectional views of an example of an integrated cooling assembly. FIG. 4 shows a cold plate 406 attached to a substrate 202 using adhesive 436. The cold plate 406 is similar to the cold plate 206, except that a side wall 406C extends downwardly from sides of the base surface 406B to the substrate 202 and the side wall 406C is attached to the substrate 202 using adhesive 436. Adhesive 436 may be similar to adhesive 236.

Instead of the semiconductor device layer 204 comprising the semiconductor device 303 disposed in a molding material 305 of FIG. 3A, FIG. 4 shows the semiconductor device 303 without the molding material 305. The side wall 406C of the cold plate is disposed adjacent to a side wall of the semiconductor device 303 such that surfaces of both side walls face each other. The side wall 406C of the cold plate is spaced laterally apart (in the Y-axis direction) from a side wall of the semiconductor device 303 to define a side channel therebetween. The side channel is in fluid communication with the coolant channel 210, the cavity coolant channels, and the inlet/outlet openings 206A. Coolant fluid may flow through the side channel, the coolant channel 210, and the cavity coolant channels.

In some embodiments, the side wall 406C may be a uniform thickness. In some embodiments, as shown in FIG. 4, the side wall 406C may have a smaller thickness in a lower portion of the side wall 406C that extends to the substrate 202. For example, cold plate 406 may be similar to cold plate 206, except an exterior portion of the side wall 206C is extended to reach the substrate 202. Extending an exterior portion of the side wall 206C increases a size of a cavity around the semiconductor device 303. Furthermore, the side channel may be defined between a lower portion of the side wall 406C and a side of the semiconductor device 303.

As shown in FIG. 4 and described above in relation to FIG. 3A, the cavity dividers 206D may be separated from a surface of semiconductor device 303 by a gap. In other embodiments, as shown in FIG. 4 and described above in relation to FIG. 3B, the cavity dividers 206D may be attached to the surface of the semiconductor device 303 using adhesive 234.

In some embodiments, as shown in FIG. 4, a shim 435 may separate the cold plate 406 from a surface of the substrate 202 by a distance corresponding to the gap. In some embodiments, adhesive 433 and a shim 435 may be used. The shim 435 may be similar to shim 335. The adhesive 433 may be similar to adhesive 436 except it is disposed adjacent to shim 435. The cavity dividers 206D may be spaced apart from the semiconductor device 303 a distance corresponding to the gap. For example, a height of the cold plate 406 may be the sum of the height of cold plate 206 and the height the semiconductor device 303.

In some embodiments, the height of the side wall 406C may be the sum of the height of cold plate 206, the height of semiconductor device 303, and an offset. The offset may be selected to produce a gap between the cavity dividers 206D and the semiconductor device 303 without use of a shim.

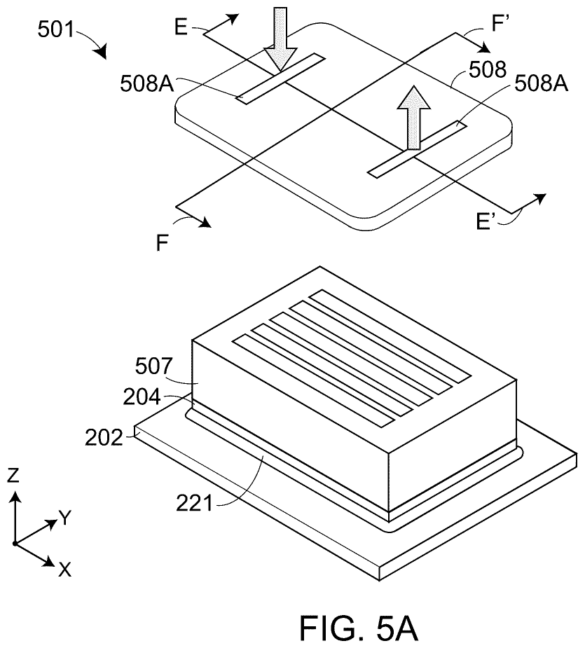

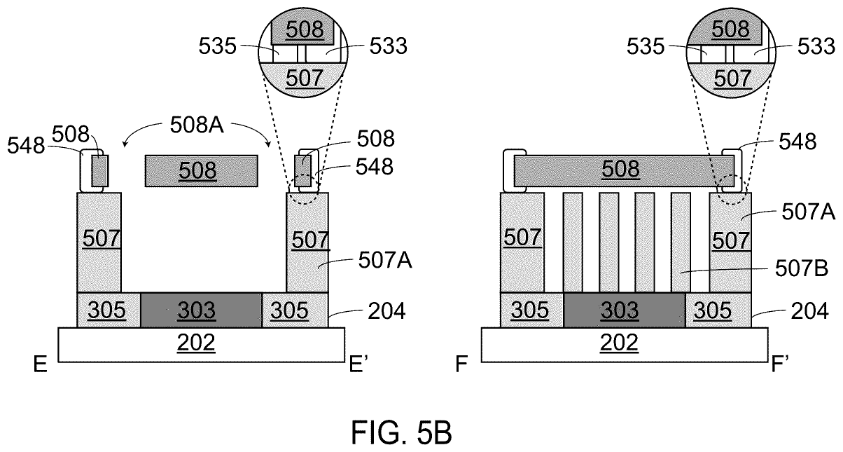

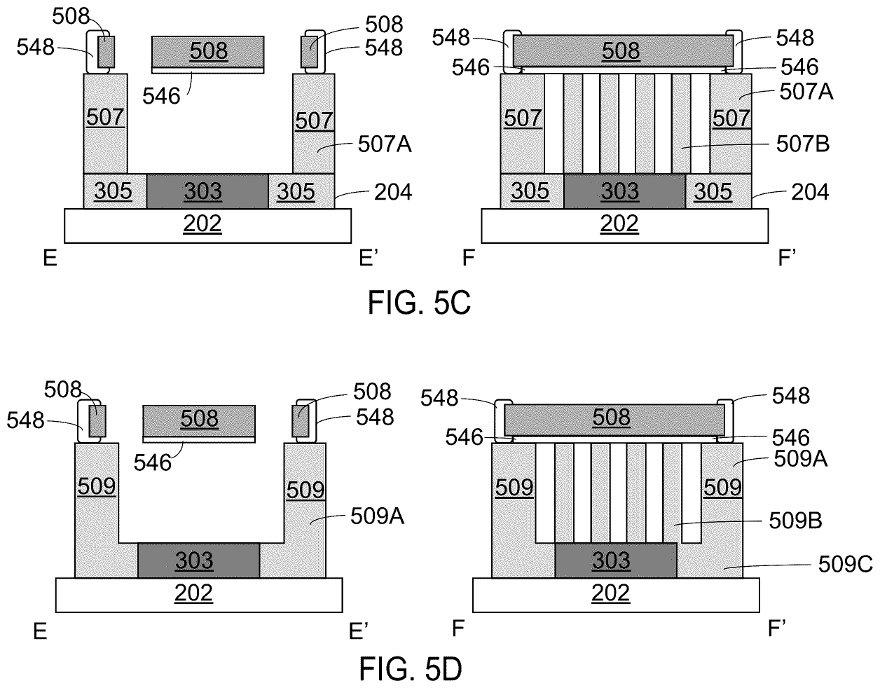

FIG. 5A is a schematic exploded isometric view of a device package 501, in accordance with some embodiments of the disclosure. The device package 501 comprises an integrated cooling assembly. FIGS. 5B, 5C, and 5D are examples of a schematic sectional view taken along the line E-E′ and a schematic sectional view taken along the line F-F′ of FIG. 5A.

FIGS. 5B and 5C shows an integrated cooling assembly that comprises a semiconductor device 303, a manifold 507 disposed on the semiconductor device 303, and a metal cover 508. The semiconductor device 204 is disposed in a molding material 305. The cover 508 is attached to the manifold 507. In some embodiments, the cover 508 is attached to the manifold 507 using adhesive 548 along edges of the cover 508. The adhesive 548 may be similar to adhesive 238. As shown, the cover 508 extends laterally across an upper surface of the manifold 507 such that a perimeter wall of the cover 508 is substantially flush with the side wall of the manifold 507.

The manifold 507 comprises a side wall 507A and cavity dividers 507B. The side wall 507A extends between the molding material 305 and the cover 508. The plurality of cavity dividers 507B extend between a backside of the semiconductor device 303 and the cover 508. The cavity dividers 507B extend laterally between the inlet opening 508A and the outlet opening 508A. The cavity dividers 507B are spaced apart from each other to define plural cavity channels therebetween. In some embodiments, the cavity dividers 507B are thermally conductive. For example, the cavity dividers 507B may comprise a molding material loaded with particles to make the cavity dividers 507B more thermally conductive. In some embodiments, the manifold 507 is thermally conductive. For example, the manifold 507 comprises a molding material loaded with particles to make the manifold 507 more thermally conductive.

In some embodiments, the cover 508 comprises a base surface, which faces a semiconductor device, and an opposite second surface. Inlet and outlet openings 508A are formed through the cover 508 by extending between the base surface and the opposite second surface. Coolant fluid enters the integrated cooling assembly through the inlet opening 508A, flows through channels defined by the cavity dividers 507B, and exits the integrated cooling assembly via the outlet opening 508A. The cover 508 may retain the fluid in the coolant channel 210 as the fluid flows between the inlet/outlet openings 508A.

In some embodiments, as shown in FIG. 5B, the cavity dividers 507B are separated from a surface of the cover 508 by a gap. The upper surface of the cavity dividers 507B may be close enough to the cover 508 so that the fluid is retained (or primarily remains) within separate cavity coolant channels while traveling across the backside of the semiconductor device 303 (e.g., less than about 2%, or less than about 1%, or less than about 0.5%, or less than about 0.1% of the fluid flow may travel from one channel to another channel). In some embodiments, upper surfaces of the cavity dividers 507B are spaced apart from a surface of the cover 508 to define a gap of less than about 100 microns, or less than about 150 microns, or less than about 200 microns.

In some embodiments, as shown in FIG. 5B, the cover 508 is attached to the manifold 507 using adhesive 533 along the edges of the cover 508. The adhesive 533 may be similar to adhesive 548, except that adhesive 548 is laterally adjacent to a shim 535. The shim 535 may be similar to shim 435 or shim 335. The shim 535 may separate a surface of the cover 508 to a surface of the manifold 507 by a distance corresponding to the gap.

In some embodiments, as shown in FIG. 5C, the cavity dividers 507B are attached to the base surface of the cover 508 using adhesive 546. In some embodiments, the cover 508 may be attached to the manifold 507 using adhesive 546. For example, adhesive 546 may be disposed between the base surface of the cover 508 and the manifold 507. In some embodiments, adhesive 546 may be used instead of adhesive 548. In some embodiments, both adhesive 546 and adhesive 548 may be used to attach the cover 508 to the manifold 507. In some embodiments, a non-adhesive material may be used instead of adhesive 546, e.g., pressed between the cover 508 and the manifold 507. For example, a non-adhesive material may be a polymer. In some embodiments, the adhesive 546 or non-adhesive material may be applied on one side and pressed from the other side (e.g., adhesive 546 or non-adhesive material applied to cavity dividers 507B and pressed from the cover 508, or applied to the cover 508 and pressed from the cavity dividers 507B).

In some embodiments, as shown in FIG. 5D, a molding portion 509 comprises the molding material 305 and the manifold 507. That is, the molding material 305 and the manifold 507 and formed together as a single molding portion 509. For example, the molding portion 509 may be formed around and on the semiconductor device 303. The cover 508 may be attached to the molding portion 509 using adhesive 548. The molding portion 509 may comprise side walls 509A corresponding to 507A and cavity dividers 509B corresponding to 507B. The molding portion 509 may comprise a base portion 509C corresponding to the molding material 305.

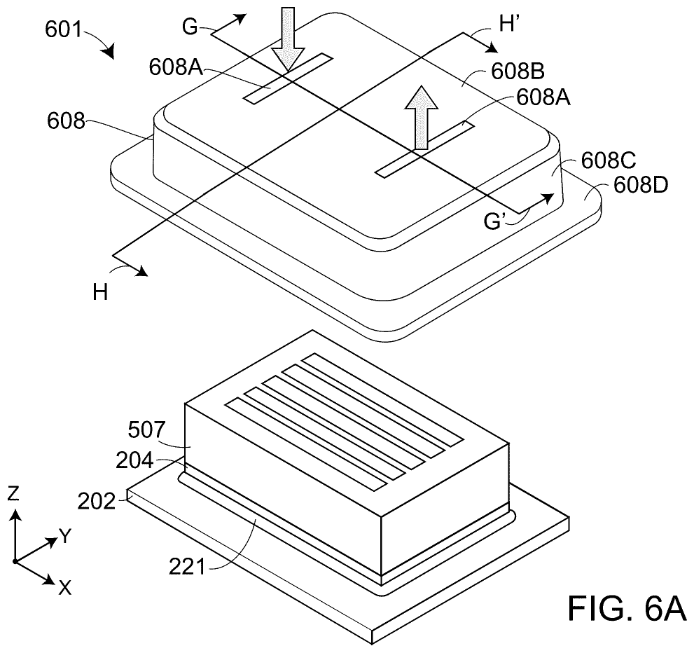

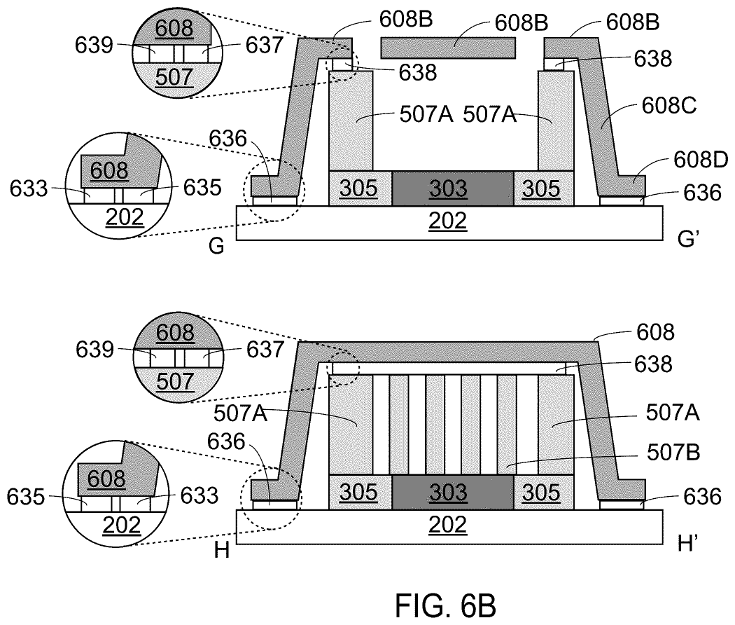

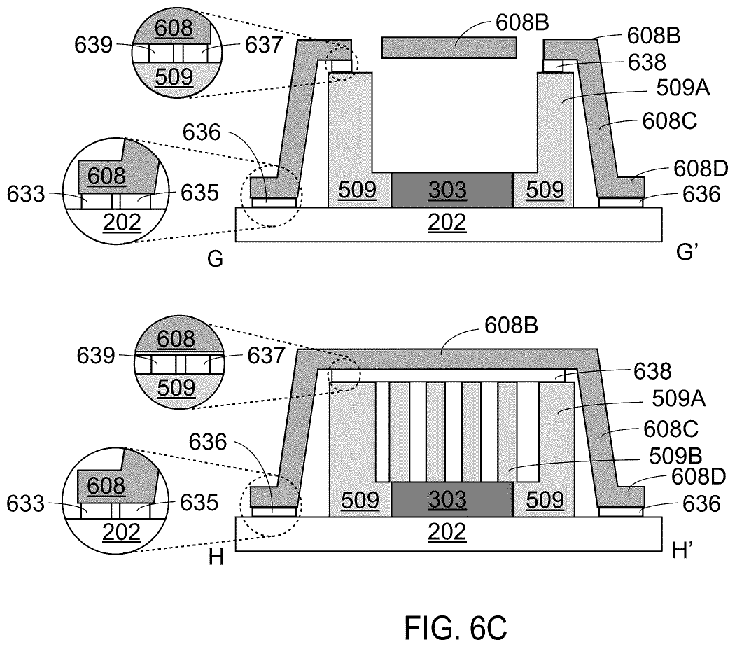

FIG. 6A is a schematic exploded isometric view of a device package 601, in accordance with some embodiments of the disclosure. FIGS. 6B and 6C are schematic sectional views of examples of the device package of FIG. 6A taken along the line G-G′ and line H-H′, in accordance with some embodiments of the disclosure.

Device package 601 comprises an integrated cooling assembly. Device package 601 is similar to device package 501 except that instead of a metal cover 508 attached to a manifold 507, a metal cover 608 is attached to the substrate 202. The cover 608 is similar to cover 508 in that the cover 608 comprises a top portion 608B with openings 608A through the top portion 608B (e.g., top portion 608B is similar to cover 508). However, the cover 608 also comprises a side portion 608C and a lateral portion 608D. As shown in FIGS. 6A-6C, the cover 608 comprises a base surface, which faces a semiconductor device, and an opposite second surface. Inlet and outlet openings 608A are formed through the cover 608 by extending between the base surface and the opposite second surface. The side portion 608C extends from the top portion downwardly toward the substrate 202. The lateral portion 608D extends laterally across the substrate 202 from the side portion 608C. The lateral portion 608D may extend partially or entirely across an upper surface of the substrate 202 towards a perimeter sidewall of the substrate 202. In some embodiments, the lateral portion 608D is attached to the substrate 202 using adhesive 636. Adhesive 636 may be similar to adhesive 236. Coolant fluid enters the integrated cooling assembly through the inlet opening 608A, flows through cavity channels defined by cavity dividers 507B, and exits the integrated cooling assembly via the outlet opening 608A. It will be understood that the openings may be reversed.

In some embodiments, cavity dividers 507B are attached to the cover 608 using adhesive 638. In some embodiments, the cover 608 is attached to the manifold 507 with adhesive 638. Adhesive 638 may be similar to adhesive 546. Adhesive 638 may be formed on the base surface of the cover 608 and attached to the manifold 507.

In other embodiments, the cavity dividers 507B may be separated from a surface of the cover 608 by a gap. For example, adhesive 638 may be optional, and the cover 608 is not attached to the manifold 507 using adhesive 638. Upper surfaces of the cavity dividers 507B may be close enough to the cover 608 so that the fluid is retained (or primarily remains) within separate cavity coolant channels while traveling across the backside of the semiconductor device 303 (e.g., less than about 2%, or less than about 1%, or less than about 0.5%, or less than about 0.1% of the fluid flow may travel from one channel to another channel). In some embodiments, the upper surfaces of the cavity dividers 507B are spaced apart from a base surface of the cover 608 to define a gap of less than about 100 microns, or less than about 150 microns, or less than about 200 microns.

In some embodiments, the cover 608 is attached to the substrate 202 using adhesive 633 along the edges of the cover 608. The adhesive 633 may be similar to adhesive 636, except that adhesive 633 is laterally adjacent to a shim 635. The shim 635 may be similar to shim 535 or shim 435 or shim 335. The shim 635 may separate a surface of the cover 608 to a surface of the substrate 202 by a distance corresponding to the gap.

In some embodiments, the cover 608 is attached to manifold 507 using adhesive 639. Adhesive 639 may be similar to adhesive 638 except it is disposed laterally adjacent to the shim 637. The shim 637 may be similar to shim 635 or shim 535 or shim 435 or 335. The shim 637 may separate the cover 608 from the surface of the manifold 507 by a distance corresponding to the gap.

In some embodiments, a thermally conductive coating may be disposed on surfaces of the manifold 507 and/or surfaces of the cover 608 exposed to fluid flowing through the coolant channel. The thermally conductive coating may be a metallic coating comprising a metal material such as copper, nickel, etc. that is sputtered or plated on the surfaces. The thermally conductive coating may have a roughened surface to help with turbulence of the fluid flowing through the coolant channel and improve heat extraction.

In some embodiments, as shown in FIG. 6C, a molding portion 509 comprises the molding material 305 and the manifold 507. That is, the molding material 305 and the manifold 507 and formed together as a single molding portion 509. For example, the molding portion 509 may be formed around and on the semiconductor device 303. The cover 508 may be attached to the molding portion 509 using adhesive 548.

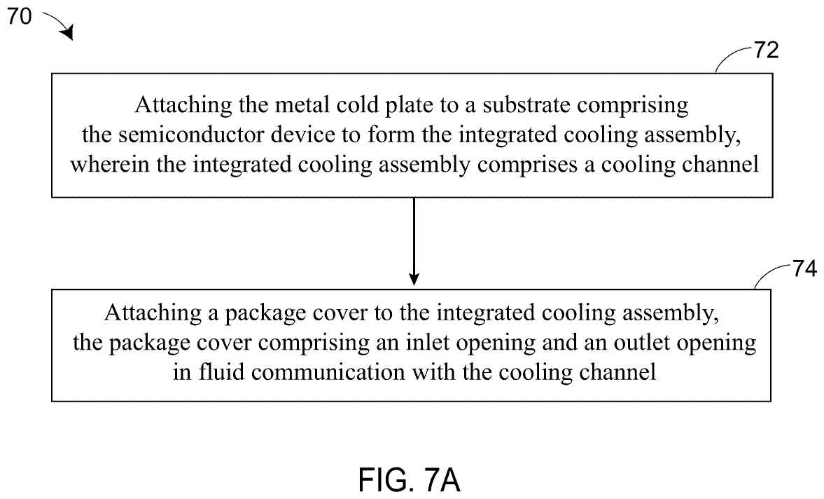

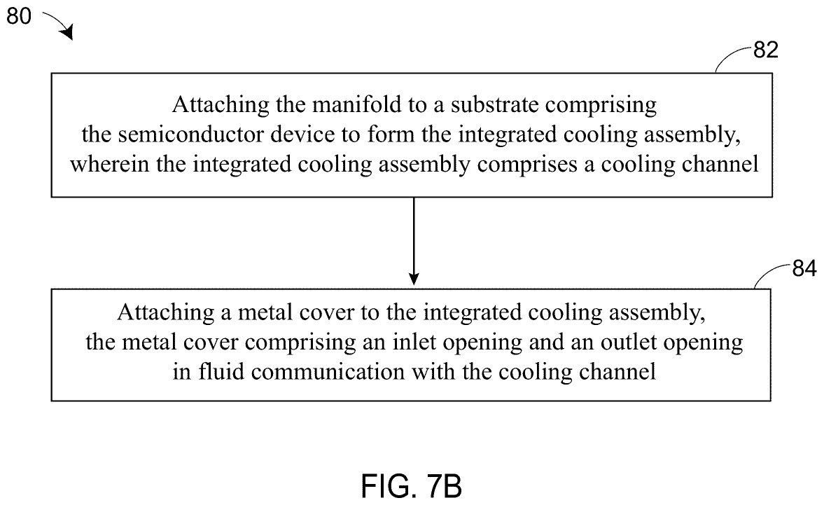

FIG. 7A is a flow diagram setting forth a method 70 of manufacturing a device package 201, according to embodiments of the disclosure.

Method 70 is a method of manufacturing a device package 201 in which the metal cold plate 206 is attached to a substrate 202 comprising the semiconductor device 303 to form an integrated cooling assembly comprising a cooling channel.

The semiconductor device 303 may be disposed on the substrate 202 without molding material (e.g., as shown in FIG. 4). In such embodiments, at block 72, the method 70 may include attaching the cold plate 406 to the substrate 202 using adhesive 436. For example, the method may include attaching a bottom surface of side wall 406C to the substrate 202 using adhesive 436. In some embodiments, method 70 may further comprise forming cavity dividers 406D in the cold plate 406 and attaching the cavity dividers 406D to a backside of the semiconductor device 303 using adhesive 234. At block 74, the method 70 includes attaching a cover (e.g., package cover 208) to the integrated cooling assembly 203 using adhesive, the cover comprising an inlet opening and an outlet opening in fluid communication with the cooling channel (e.g., openings 212).

The semiconductor device 303 may be disposed in molding material 305 on the substrate 202 (e.g., as shown in FIGS. 3A, 3B, 3C). In such embodiments, the method 70 comprises forming molding material 305 around the semiconductor device 303. At block 72, the method 70 may include attaching the cold plate 206 to the molding material 305 using adhesive 242. For example, the method may include attaching a bottom surface of side wall 206C to the molding material 305 using adhesive 242.

FIG. 7B is a flow diagram setting forth a method 80 of manufacturing a device package 501 or device package 601, according to embodiments of the disclosure.

Method 80 is a method of manufacturing a device package 501 or device package 601 in which the manifold 507 is attached to a substrate comprising the semiconductor device 303 to form the integrated cooling assembly comprising a cooling channel.

At block 82, the method 80 may include attaching the manifold 507 to a substrate comprising the semiconductor device 303. For example, the substrate may comprise the semiconductor device 303 disposed in a molding material 305.

At block 84, the method 80 includes attaching a metal cover (e.g., cover 508 or cover 608) to the integrated cooling assembly, the metal cover comprising an inlet opening and an outlet opening (e.g., openings 508A or 608A) in fluid communication with the cooling channel.

The package device 501 may include a cover 508 (e.g., as shown in FIGS. 5A-5D). In such embodiments, at block 84, the method 80 may include attaching the cover 508 to the manifold 507 using adhesive 548 along the edges of the cover 508 as shown in FIG. 5B, and/or attaching the cover 508 to the manifold 507 using 546 on a bottom surface of cover 508. In some embodiments, method 80 may further comprise forming cavity dividers 507B in the manifold 507 and attaching the cavity dividers 507B to the cover 508 using adhesive 546.

The package device 601 may include a cover 608 (e.g., as shown in FIGS. 6A-6C). In such embodiments, at block 84, the method 80 may include attaching the cover 608 to the manifold 507 using adhesive 638, and/or attaching the cover 608 to the substrate 202 using adhesive 636. The semiconductor device 303 may be disposed in a molding material 305, and may be disposed on a substrate 202. In some embodiments, method 80 may further comprise forming cavity dividers 507B in the manifold 507 and attaching the cavity dividers 507B to the cover 608 using adhesive 638.

FIG. 8A is a schematic sectional view of a multi-component device package 801 that includes a cold plate 806 and two or more devices. The cold plate 806 may be attached using adhesive to the backside surfaces of two or more devices. As shown, the device package 801 is similar to device package 201, except that the integrated cooling assembly 803 may include a plurality of devices 804A (one shown) which may be singulated and/or disposed in a vertical device stack 804B (one shown), and a cold plate 806 may be attached to each of the devices 804A and device stack 804B using adhesive. In some embodiments, the device 804A may comprise a processor and the device stack 804B may comprise a plurality of memory devices. Here, the device 804A and the device stack 804B are disposed in a side-by-side arrangement on the package substrate 202 and are in electrical communication with one another through conductive elements formed in, on, or through the package substrate 202. Here, the cold plate 806 may be sized to provide a surface for attachment to both the device 804A and the device stack 804B using adhesive but may otherwise be the same or substantially similar to other cold plates described herein. For example, the cold plate may include any one or combination of the features of the cold plates described in relation to other figures herein. In some embodiments, cold plate 806 may comprise similar features as cold plate 206. For example, here the cold plate 806 comprises a base surface 806B, side wall 806C, and cavity dividers (e,g., cavity dividers 206D). A base surface 806B faces the device 804A and device stack 804B, and an opposite second surface faces the package cover 208. The base surface 806B and the second surface are opposite surfaces of a top portion of the cold plate 806. The device 804A and the device stack 804B may define the coolant chamber volume 810. Here, the coolant chamber volume 810 and a underfill layer 840 or other molding material disposed in the gap regions between the device 804A and the device stack 804B provide the bottom of the coolant chamber volume 810 disposed between the device 804A and the device stack 804B.

An adhesive 838, disposed between the cold plate 806 and package cover 208, attaches the cold plate 806 to the package cover 208 and forms a coolant-impermeable barrier therebetween. Coolant is circulated to the device package 801 through the inlet/outlet openings 212 of the package cover 208 and flows through the coolant chamber volume 810 via openings in the integrated cooling assembly and corresponding openings formed through the adhesive 838. Here, the adhesive 838 may be formed of a polymer or epoxy molding material, such as described above, or a compliant adhesive layer, such as a thermal interface material (TIM) layer. For example, adhesive 838 may be similar to adhesive 238.

Although device package 801 shows device 804A and device stack 804B in an embodiment related to device package 201, a similar type of configuration may be applied to other embodiments (e.g., device package 501, 601). For example, instead of a semiconductor device 303 disposed in a molding material 305, there may be a device 804A and device stack 804B disposed in a molding material.

FIG. 8B is a schematic side sectional view in the X-Z plane of an example of a multi-component device package 891 that includes a cold plate 807 attached to the backside surfaces of two or more devices 804A, 804B. The multi-component device package 891 may be similar to the device package 291 described above, and therefore the description of similar features is omitted for brevity. FIG. 8B shows a multi-component device package 891 which is similar to the device package 801 of FIG. 8A, except it includes a sealing material layer 822. In some embodiments, the sealing material layer 822 is similar to the sealing material layer 222. For example, the sealing material layer 822 of the device package 891 as shown in FIG. 8B may be used in place of the adhesive 838 and the adhesive 236 as shown in the device package 801 in FIG. 8A. In some embodiments, cold plate 806 may be used in place of cold plate 807 in FIG. 8B. In some embodiments, cold plate 807 may be used in place of cold plate 806 in FIG. 8A. Unlike the view of FIG. 8A which shows a cross section of the cold plate 806 at a coolant channel 810, the sectional view in FIG. 8B shows a cross section of the cold plate 807 at a cavity divider 807D. A description of similar components in FIGS. 8A and 8B can be found in either and/or both of the description relevant to FIGS. 8A and 8B. In some embodiments, cold plate 807 may comprise similar features as cold plate 207. The description of components or features of the device package 891 in FIG. 8B may be applied to the device package 801 of FIG. 8A. In some embodiments, the two or more devices 804A and 804B are reconstituted and then bonded to the cold plate 807. As shown, the device package 891 includes a package substrate 202, an integrated cooling assembly 813 and a package cover 208. The integrated cooling assembly 813 may include a plurality of devices 804A (one shown) that may be singulated and/or disposed in a vertical device stack 804B (one shown). The cold plate 807 may be attached to each of the devices 804A and device stack 804B, e.g., with adhesive or other methods including flip chip bonding, etc. In some embodiments, the device 804A may comprise a processor, and the device stack 804B may comprise a plurality of memory devices. Here, the device 804A and the device stack 804B are disposed in a side-by-side arrangement on the package substrate 202 and are in electrical communication with one another through conductive elements formed in, on, or through the package substrate 202. Here, the cold plate 807 is sized to provide a bonding surface for attachment to both the device 804A and the device stack 804B but may otherwise be the same or substantially similar to other cold plates described herein. For example, the cold plate may include any one or combination of the features of the cold plates described in relation to other figures herein. In some embodiments, the lateral dimensions (or footprint) of the cold plate 807 may be smaller or larger than the combined lateral dimensions (or footprint) of both the device 804A and the device stack 804B. In some embodiments, one or more sidewalls of the cold plate 807 may be aligned or offset to the vertical sidewalls of the device 804A and the device stack 804B (including inside or outside their footprint).

The methods described above advantageously improves the efficiency of heat transfer from the backside of one or more devices to a coolant fluid by guiding the coolant fluid to flow through channels on the backside surface of the one or more semiconductor devices as it passes through the coolant chamber volume. The fluid is guided to flow over the semiconductor device. Each channel may have a same quantity of fluid passing through a channel. The method may enable heat from one or more devices to transfer heat through a stationary material and fluid flow. In regards to a stationary material, heat from one or more semiconductor devices may be transferred through adhesive (e.g., adhesive with thermally conductive particles) to a metal cold plate or through a molding layer to a metal cover. In regards to fluid flow, heat from one or more semiconductor devices may be transferred through coolant fluid contacting a backside surface of one or more devices.

In some embodiments, the integrated cooling assembly and the package cover may be formed of CTE mismatched materials and attached to one another using a flexible material to form the sealing material layer or adhesive, or by use of a decoupling adhesive layer disposed between the sealing material layer or adhesive and one of the cold plate or the package cover. The flexible material may absorb the difference in linear expansion between the package cover and the cold plate during repeated thermal cycles to extend the useful lifetime of the device package.

The embodiments discussed above are intended to be illustrative and not limiting. One skilled in the art would appreciate that individual aspects of the cooling assemblies, device packages, and methods discussed herein may be omitted, modified, combined, and/or rearranged without departing from the scope of the disclosure.

1. A device package comprising:
an integrated cooling assembly comprising a semiconductor portion and a metal cold plate attached to the semiconductor portion, wherein:
the semiconductor portion comprises a semiconductor device;
the metal cold plate comprises:
a base surface spaced apart from the semiconductor device to collectively define a coolant channel therebetween;
a side wall extending downwardly from the base surface to define a perimeter of the coolant channel; and
a plurality of cavity dividers extending downwardly from the base surface towards the semiconductor device.

2. The device package of claim 1, wherein:
the base surface comprises an inlet opening and an outlet opening; and
the coolant channel is in fluid communication with the inlet opening and the outlet opening.

3. The device package of claim 2, wherein:
the cavity dividers extend laterally between the inlet opening and the outlet opening; and
the cavity dividers are spaced apart from each other to define plural cavity coolant channels therebetween.

4. The device package of claim 1, wherein lower surfaces of the cavity dividers are spaced apart from a backside of the semiconductor device to define a gap of less than about 100 microns.

5. The device package of claim 1, wherein lower surfaces of the cavity dividers are spaced apart from a backside of the semiconductor device to define a gap of less than about 150 microns.

6. The device package of claim 1, wherein lower surfaces of the cavity dividers are spaced apart from a backside of the semiconductor device to define a gap of less than about 200 microns.

7. The device package of claim 1, further comprising a shim separating the metal cold plate from backside of the semiconductor device by a distance corresponding to the gap.

8. The device package of claim 1, wherein the cavity dividers are attached to the semiconductor device using adhesive.

9. The device package of claim 1, wherein:
the semiconductor portion comprises molding material and the semiconductor device is disposed in the molding material;
the side wall of the metal cold plate extends downwardly from sides of the base surface to the molding material; and
the side wall is attached to the molding material using adhesive.

10. The device package of claim 1, wherein:
the semiconductor device is disposed on a substrate;
the side wall of the metal cold plate extends downwardly from the base surface to the substrate; and
the side wall is attached to the substrate using adhesive.

11. The device package of claim 10, wherein:
the side wall of the metal cold plate is disposed adjacent to a side wall of the semiconductor device; and
the side wall of the metal cold plate is spaced laterally apart from the side wall of the semiconductor device to define a side channel therebetween; and
the side channel is in fluid communication with the coolant channel.

12. The device package of claim 1, further comprising a coolant fluid disposed in the coolant channel.

13. A device package comprising:
an integrated cooling assembly comprising a semiconductor device disposed in a molding material, a manifold disposed on the semiconductor device, and a metal cover attached to the manifold, wherein:
the manifold comprises:
a side wall extending between the molding material and the metal cover; and
a plurality of cavity dividers extending between a backside of the semiconductor device and the metal cover; and
the side wall, a base surface of the metal cover, and a backside of the semiconductor device collectively define a coolant channel therebetween.

14. The device package of claim 13, wherein:
the metal cover comprises an inlet opening and an outlet opening; and
the coolant channel is in fluid communication with the inlet opening and the outlet opening.

15. The device package of claim 13, wherein the metal cover is attached to the manifold using adhesive along edges of the metal cover.

16. The device package of claim 13, wherein the cavity dividers are attached to a surface of the metal cover using adhesive.

17. The device package of claim 13, wherein the molding material and the manifold form a single molding portion.

18. The device package of claim 13, wherein:
the semiconductor device is disposed on a substrate;
the metal cover further comprises:
a top portion;
a side portion extending from the top portion downwardly towards the substrate; and
a lateral portion extending laterally across the substrate from the side portion;
the lateral portion is attached to the substrate using adhesive; and
the top portion is attached to the manifold using adhesive.

19. A method of manufacturing the device package of claim 1, the method comprising:
attaching the metal cold plate to a substrate comprising the semiconductor device to form the integrated cooling assembly, wherein the integrated cooling assembly comprises a cooling channel.

20. (canceled)

21. A method of manufacturing the device package of claim 13, the method comprising:
attaching the manifold to a substrate comprising the semiconductor device to form the integrated cooling assembly, wherein the integrated cooling assembly comprises a cooling channel.

22. (canceled)
